(19) United States
(12) Patent Application Publication
(10) Pub. No.: US 2025/0163228 A1
(43) Pub. Date: May 22, 2025

(54) POLYESTER RESIN, RESIN COMPOSITION, CURED PRODUCT THEREOF, AND USE THEREOF

(71) Applicant: AJINOMOTO CO., INC., Tokyo (JP)

(72) Inventors: Ichiro OGURA, Kanagawa (JP); Naoya SATO, Kanagawa (JP); Shunsuke TANAKA, Kanagawa (JP)

(73) Assignee: AJINOMOTO CO., INC., Tokyo (JP)

(21) Appl. No.: 19/023,976

(22) Filed: Jan. 16, 2025

Related U.S. Application Data
(63) Continuation of application No. PCT/JP2023/025561, filed on Jul. 11, 2023.

(30) Foreign Application Priority Data
Jul. 21, 2022 (JP) 2022-116746

(51) Int. Cl. C08J 5/24; C08G 59/42; C09D 163/00; H01L 23/29

(52) U.S. Cl. CPC C08J 5/24; C08G 59/4223; C09D 163/00; C08J 2363/00; H01L 23/293

(57) ABSTRACT

Provided is a novel polyester resin that achieves a cured product exhibiting excellent dielectric properties in combination with a cross-linkable resin. The polyester resin is represented by the following general formula (1):

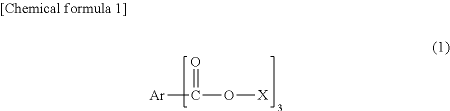

(in the formula,
   Ar represents an aromatic ring optionally having a substituent, and
   X each independently represents a monovalent organic group containing an aromatic ring,
   provided that one or more X out of three X contain at least two aromatic rings, and the total number of carbon atoms constituting these aromatic rings is 16 or more).

### TECHNICAL FIELD

The present invention relates to a polyester resin. Furthermore, the present invention relates to a resin composition containing the polyester resin, a cured product thereof, and use thereof for a resin sheet, a prepreg, a printed wiring board, a semiconductor chip package, and a semiconductor device.

### BACKGROUND

A resin composition containing a cross-linkable resin such as an epoxy resin and a cross-linking agent (curing agent) for the resin is widely used as a material for an electronic component such as a semiconductor package and a printed wiring board, since it produces a cured product that is excellent in insulation, heat resistance, adhesion, and the like.

On the other hand, high-speed communication such as a 5th generation mobile communication system (5G) has a problem of transmission loss during operation in a high-frequency environment. To cope with such a problem, an insulation material with excellent dielectric properties (low dielectric constant and low dielectric loss tangent) is required.

As an insulation resin material having excellent dielectric properties, for example, Patent Literature 1 discloses, as a cross-linking agent for an epoxy resin, an active ester resin that is a reaction product of a divalent aromatic hydroxy compound and an aromatic diacid chloride. Furthermore, Patent Literature 2 discloses a bifunctional or trifunctional active ester resin having an unsaturated bond-containing substituent.

### RELATED ART REFERENCE

### Patent Literature

Patent Literature 1: Japanese Patent Application Laid-Open No. 2009-235165 A
Patent Literature 2: International Publication No. 2018/235424

### SUMMARY OF INVENTION

### Problem to be Solved by the Invention

The active ester resins described in Patent Literatures 1 and 2 have significantly excellent dielectric properties as compared with a conventional phenol-based cross-linking agent and the like. However, the transmission loss required for 5G applications is not of a sufficiently satisfactory level.

An object of the present invention is to provide a novel polyester resin that achieves a cured product exhibiting excellent dielectric properties in combination with a cross-linkable resin.

### Means for Solving Problem

As a result of intensive studies, the present inventors have found that a cured product exhibiting excellent dielectric properties in combination with a cross-linkable resin can be achieved by a polyester resin having the following configuration, thereby completing the present invention.

That is, the present invention includes the following content.
[1]A polyester resin (X) represented by the following general formula (1):

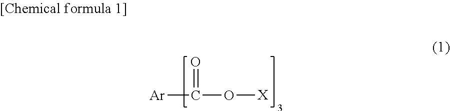

(in the formula,
   Ar represents an aromatic ring optionally having a substituent, and
   X each independently represents a monovalent organic group having an aromatic ring,
   provided that one or more X out of three X contain at least two aromatic rings, and a total number of carbon atoms constituting the aromatic rings is 16 or more).
[2] The polyester resin (X) according to [1], wherein the X is each independently a monovalent organic group represented by the following general formula (2):

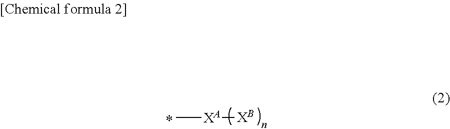

(in the formula,
   X^{A} represents a (1+n)-valent organic group containing at least one aromatic ring,
   X^{B} each independently represents a monovalent organic group having at least one aromatic ring,
   n represents an integer of 0 to 6, and
   * represents a bond to a carbonyloxy group,
   provided that, in one or more X out of three X, n represents an integer of 1 to 6, and a total number of carbon atoms constituting the aromatic rings contained in X is 16 or more).
[3] The polyester resin (X) according to [1] or [2], wherein one or more X out of three X contain a condensed polycyclic aromatic ring.
[4] The polyester resin (X) according to [1] or [2], wherein one or more X out of three X contain three or more aromatic rings.
[5] The polyester resin (X) according to any one of [2] to [4], wherein the X^{A} is each independently a (1+n)-valent organic group represented by the following general formula (A):

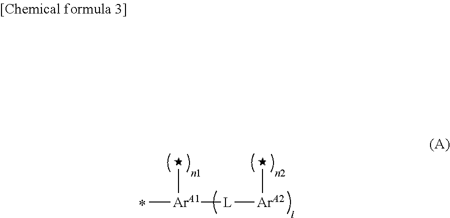

(in the formula,
   Ar^{A1} and Ar^{A2} each independently represent an aromatic ring optionally having a substituent,
   L represents a single bond or a divalent linking group,
   l 0 or 1,
   n1 and n2 are integers that satisfy n1+n2=n,
   * represents a bond to a carbonyloxy group, and
   a solid star mark represents a bond to X^{B}).
[6] The polyester resin (X) according to any one of [2] to [5], wherein the X^{B} is each independently a monovalent organic group represented by the following general formula (B):

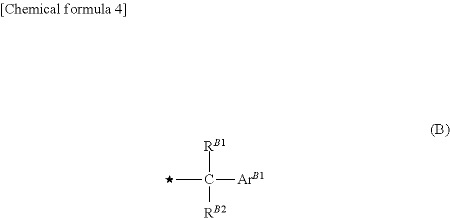

(in the formula,
   R^{B1} and R^{B2} each independently represent a hydrogen atom or an alkyl group,
   Ar^{B1} represents an aromatic ring optionally having a substituent, and
   a solid star mark represents a bond to X^{A}).
[7] The polyester resin (X) according to any one of [1] to [6], wherein the polyester resin is represented by the following general formula (1-1):

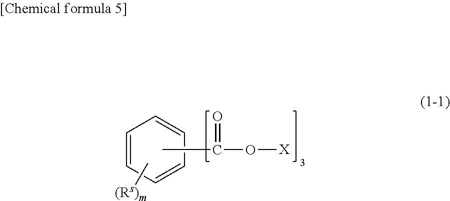

(in the formula,
   X represents the same definition as described above,
   R^{s} each independently represents a substituent, and
   m represents an integer of 0 to 3).
[8] The polyester resin (X) according to any one of [1] to [7], wherein the polyester resin is a condensation reaction product of:
   (x1) an aromatic tricarboxylic acid compound or an aromatic tricarboxylic acid halide compound; and
   (x2) an aromatic monohydroxy compound containing at least an aromatic monohydroxy compound that contains at least two aromatic rings and in which a total number of carbon atoms constituting these aromatic rings is 16 or more.
[9]A resin cross-linking agent comprising the polyester resin (X) according to any one of [1] to [8].
[10]A resin composition comprising the polyester resin (X) according to any one of [1] to [8], and a cross-linkable resin (Y).
[11] The resin composition according to [10], wherein the cross-linkable resin (Y) is one or more types selected from the group consisting of a thermosetting resin and a radically polymerizable resin.
[12] The resin composition according to [10] or [11], further comprising an inorganic filler.
[13] The resin composition according to any one of [10] to [12], further comprising an organic solvent.
[14] The resin composition according to any one of [10] to [13], for an insulation layer of a printed wiring board.
[15] The resin composition according to any one of [10] to [13], for semiconductor sealing.
[16]A resin sheet comprising: a support; and a layer of the resin composition according to any one of [10] to [15], disposed on the support.
[17] The resin sheet according to [16], wherein the support is a thermoplastic resin film or a metal foil.
[18]A prepreg formed by impregnating a sheet-like fiber substrate with the resin composition according to any one of [10] to [15].
[19]A cured product of the resin composition according to any one of [10] to [15].
[20]A printed wiring board comprising an insulation layer formed of a cured product of the resin composition according to any one of [10] to [15].
[21]A semiconductor chip package comprising a sealing layer formed of a cured product of the resin composition according to any one of [10] to [13] and [15].
[22] The semiconductor chip package according to [21], wherein the semiconductor chip package is a Fan-Out type package.
[23]A semiconductor device comprising a layer made of the cured product according to [19].

### Effect of the Invention

According to the present invention, a novel polyester resin that achieves a cured product exhibiting excellent dielectric properties in combination with the cross-linkable resin can be provided.

The polyester resin of the present invention has favorable solubility in a solvent and a resin. In addition, according to the resin composition containing the polyester resin of the present invention and a cross-linkable resin, a cured product that exhibits excellent dielectric properties and is excellent in heat resistance and smear removal in the formation of via holes can be achieved.

### EMBODIMENT FOR CARRYING OUT THE INVENTION

### Description of Terms

In the present specification, the term “optionally having a substituent” with respect to a compound or group means both a case where a hydrogen atom of the compound or group is not substituted with a substituent and a case where a part or all of the hydrogen atoms of the compound or group are substituted with a substituent.

In the present specification, unless otherwise specified, the term “substituent” means a halogen atom, an alkyl group, an alkenyl group, an alkynyl group, an alkapolyenyl group, a cycloalkyl group, a cycloalkenyl group, an alkoxy group, a cycloalkyloxy group, an aryl group, an aryloxy group, an arylalkyl group, an arylalkoxy group, a monovalent heterocyclic group, an alkylidene group, an amino group, a silyl group, an acyl group, an acyloxy group, a carboxy group, a sulfo group, a cyano group, a nitro group, a hydroxy group, a mercapto group, and an oxo group. Aliphatic hydrocarbon groups having an unsaturated bond, such as an alkenyl group, an alkynyl group, an alkapolyenyl group, and a cycloalkenyl group, are also collectively referred to as an “unsaturated bond-containing substituent” or “unsaturated aliphatic hydrocarbon group”.

Examples of the halogen atom used as the substituent may include a fluorine atom, a chlorine atom, a bromine atom, and an iodine atom.

An alkyl group used as the substituent may be either linear or branched. The number of carbon atoms in the alkyl group is preferably 1 to 20, more preferably 1 to 14, further preferably 1 to 12, still further preferably 1 to 6, and particularly preferably 1 to 3. Examples of such alkyl groups may include a methyl group, an ethyl group, a propyl group, an isopropyl group, a butyl group, a sec-butyl group, an isobutyl group, a tert-butyl group, a pentyl group, a hexyl group, a heptyl group, an octyl group, a nonyl group, and a decyl group.

An alkenyl group used as the substituent may be either linear or branched. The number of carbon atoms in the alkenyl group is preferably 2 to 20, more preferably 2 to 14, further preferably 2 to 12, still further preferably 2 to 6, and particularly preferably 2 or 3. Examples of the alkenyl group may include a vinyl group, an allyl group, a 1-propenyl group, a butenyl group, a sec-butenyl group, an isobutenyl group, a tert-butenyl group, a pentenyl group, a hexenyl group, a heptenyl group, an octenyl group, a nonenyl group, and a decenyl group.

An alkynyl group used as the substituent may be either linear or branched. The number of carbon atoms in the alkynyl group is preferably 2 to 20, more preferably 2 to 14, further preferably 2 to 12, still further preferably 2 to 6, and particularly preferably 2 or 3. Examples of the alkynyl group may include an ethynyl group, a propynyl group, a butynyl group, a sec-butynyl group, an isobutynyl group, a tert-butynyl group, a pentynyl group, a hexynyl group, a heptynyl group, an octynyl group, a nonynyl group, and a decynyl group.

An alkapolyenyl group used as the substituent may be either linear or branched. The number of double bonds is preferably 2 to 10, more preferably 2 to 6, further preferably 2 to 4, and still further preferably 2. The number of carbon atoms in the alkapolyenyl group is preferably 3 to 20, more preferably 3 to 14, further preferably 3 to 12, and still further preferably 3 to 6.

The number of carbon atoms in the cycloalkyl group used as the substituent is preferably 3 to 20, more preferably 3 to 12, and further preferably 3 to 6. Examples of the cycloalkyl group may include a cyclopropyl group, a cyclobutyl group, a cyclopentyl group, and a cyclohexyl group.

The number of carbon atoms in the cycloalkenyl group used as the substituent is preferably 3 to 20, more preferably 3 to 12, and further preferably 3 to 6. Examples of the cycloalkenyl group may include a cyclopropenyl group, a cyclobutenyl group, a cyclopentenyl group, and a cyclohexenyl group.

An alkoxy group used as the substituent may be either linear or branched. The number of carbon atoms in the alkoxy group is preferably 1 to 20, more preferably 1 to 12, and further preferably 1 to 6. Examples of the alkoxy group may include a methoxy group, an ethoxy group, a propyloxy group, an isopropyloxy group, a butoxy group, a sec-butoxy group, an isobutoxy group, a tert-butoxy group, a pentyloxy group, a hexyloxy group, a heptyloxy group, an octyloxy group, a nonyloxy group, and a decyloxy group.

The number of carbon atoms in the cycloalkyloxy group used as the substituent is preferably 3 to 20, more preferably 3 to 12, and further preferably 3 to 6. Examples of the cycloalkyloxy group may include a cyclopropyloxy group, a cyclobutyloxy group, a cyclopentyloxy group, and a cyclohexyloxy group.

An aryl group used as the substituent is a group obtained by removing one hydrogen atom on an aromatic ring from an aromatic hydrocarbon. The number of carbon atoms in the aryl group used as the substituent is preferably 6 to 24, more preferably 6 to 18, further preferably 6 to 14, and still further preferably 6 to 10. Examples of the aryl group may include a phenyl group, a naphthyl group, and an anthracenyl group.

The number of carbon atoms in the aryloxy group used as the substituent is preferably 6 to 24, more preferably 6 to 18, further preferably 6 to 14, and still further preferably 6 to 10. Examples of the aryloxy group used as the substituent may include a phenoxy group, a 1-naphthyloxy group, and a 2-naphthyloxy group.

The number of carbon atoms in the arylalkyl group used as the substituent is preferably 7 to 25, more preferably 7 to 19, further preferably 7 to 15, and still further preferably 7 to 11. Examples of the arylalkyl group may include a phenyl-C₁ to C₁₂ alkyl group, a naphthyl-C₁ to C₁₂ alkyl group, and an anthracenyl-C₁ to C₁₂ alkyl group.

The number of carbon atoms in the arylalkoxy group used as the substituent is preferably 7 to 25, more preferably 7 to 19, further preferably 7 to 15, and still further preferably 7 to 11. Examples of the arylalkoxy group may include a phenyl-C₁ to C₁₂ alkoxy group and a naphthyl-C₁ to C₁₂ alkoxy group.

A monovalent heterocyclic group used as the substituent refers to a group obtained by removing one hydrogen atom from a heterocyclic ring of a heterocyclic compound. The number of carbon atoms in the monovalent heterocyclic group is preferably 3 to 21, more preferably 3 to 15, and further preferably 3 to 9. The monovalent heterocyclic group also includes a monovalent aromatic heterocyclic group (heteroaryl group). Examples of the monovalent heterocyclic ring may include a thienyl group, a pyrrolyl group, a furanyl group, a furyl group, a pyridyl group, a pyridazinyl group, a pyrimidyl group, a pyrazinyl group, a triazinyl group, a pyrrolidyl group, a piperidyl group, a quinolyl group, and an isoquinolyl group.

An alkylidene group used as the substituent refers to a group in which two hydrogen atoms are removed from the same carbon atom of an alkane. The number of carbon atoms in the alkylidene group is preferably 1 to 20, more preferably 1 to 14, further preferably 1 to 12, still further preferably 1 to 6, and particularly preferably 1 to 3. Examples of the alkylidene group may include a methylidene group, an ethylidene group, a propylidene group, an isopropylidene group, a butylidene group, a sec-butylidene group, an isobutylidene group, a tert-butylidene group, a pentylidene group, a hexylidene group, a heptylidene group, an octylidene group, a nonylidene group, and a decylidene group.

An acyl group used as the substituent refers to a group represented by the formula: —C(═O)—R (in the formula, R is an alkyl group or an aryl group). The alkyl group represented by R may be either linear or branched. Examples of the aryl group represented by R may include a phenyl group, a naphthyl group, and an anthracenyl group. The number of carbon atoms in the acyl group is preferably 2 to 20, more preferably 2 to 13, and further preferably 2 to 7. Examples of the acyl group may include an acetyl group, a propionyl group, a butyryl group, an isobutyryl group, a pivaloyl group, and a benzoyl group.

An acyloxy group used as the substituent refers to a group represented by the formula: —O—C(═O)—R (in the formula, R is an alkyl group or an aryl group). The alkyl group represented by R may be either linear or branched. Examples of the aryl group represented by R may include a phenyl group, a naphthyl group, and an anthracenyl group. The number of carbon atoms in the acyloxy group is preferably 2 to 20, more preferably 2 to 13, and further preferably 2 to 7. Examples of the acyloxy group may include an acetoxy group, a propionyloxy group, a butyryloxy group, an isobutyryloxy group, a pivaloyloxy group, and a benzoyloxy group.

The above-mentioned substituent may further have a substituent (hereinafter, sometimes referred to as a “secondary substituent”). As the secondary substituent, the same substituents as those described above may be used, unless otherwise specified.

In the present specification, the term “organic group” refers to a group that contains at least a carbon atom as a skeletal atom. The organic group may be linear, branched, or cyclic. In the present specification, the number of skeletal atoms in the organic group is preferably 1 to 3,000, more preferably 1 to 1,000, further preferably 1 to 100, still further preferably 1 to 50, and particularly preferably 1 to 30, unless otherwise specified. Examples of the organic group may include groups containing one or more skeletal atoms (including at least one carbon atom) selected from a carbon atom, an oxygen atom, a nitrogen atom, and a sulfur atom.

In the present specification, the term “aliphatic group” refers to a group in which one or more hydrogen atoms bonded to the aliphatic carbon of an aliphatic compound are removed. Specifically, a monovalent aliphatic group refers to a group obtained by removing one hydrogen atom bonded to the aliphatic carbon of an aliphatic compound, and a divalent aliphatic group refers to a group obtained by removing two hydrogen atoms bonded to the aliphatic carbon of an aliphatic compound. Examples of the divalent aliphatic group may include an alkylene group optionally having a substituent, a cycloalkylene group optionally having a substituent, an alkenylene group optionally having a substituent, a cycloalkenylene group optionally having a substituent, an alkapolyenylene group optionally having a substituent (the number of double bonds is preferably 2 to 10, more preferably 2 to 6, even more preferably 2 to 4, and still more preferably 2), and a divalent group formed from a combination thereof. In the present specification, the number of carbon atoms in the aliphatic group is preferably 1 or more, 2 or more, or 3 or more, and is preferably 50 or less, more preferably 40 or less, and even more preferably 30 or less, 20 or less, 18 or less, 16 or less, 14 or less, or 12 or less, unless otherwise specified. The number of carbon atoms does not include the number of carbon atoms of the substituent.

In the present specification, the term “aromatic ring” means a ring according to the Huckel's law in which the number of electrons contained in the π-electron system on the ring is 4p+2 (p is a natural number), and includes a monocyclic aromatic ring and a condensed polycyclic aromatic ring in which two or more monocyclic aromatic rings are condensed. The aromatic ring may be an aromatic carbocyclic ring having only carbon atoms as ring member atoms, or an aromatic heterocyclic ring having heteroatoms such as an oxygen atom, a nitrogen atom, a sulfur atom, and the like in addition to carbon atoms as ring member atoms. In the present specification, the number of carbon atoms in the aromatic ring is preferably 3 or more, more preferably 4 or more or 5 or more, and still more preferably 6 or more, and the upper limit thereof is preferably 24 or less, more preferably 18 or less or 14 or less, and still more preferably 10 or less, unless otherwise specified. The number of carbon atoms does not include the number of carbon atoms of the substituent. Examples of the aromatic ring may include monocyclic aromatic rings such as a benzene ring, a furan ring, a thiophene ring, a pyrrole ring, a pyrazole ring, an oxazole ring, an isoxazole ring, a thiazole ring, an imidazole ring, a pyridine ring, a pyridazine ring, a pyrimidine ring, and a pyrazine ring; and condensed polycyclic aromatic rings in which two or more monocyclic aromatic rings are condensed, such as a naphthalene ring, an anthracene ring, a phenanthrene ring, a benzofuran ring, an isobenzofuran ring, an indole ring, an isoindole ring, a benzothiophene ring, a benzimidazole ring, an indazole ring, a benzoxazole ring, a benzisoxazole ring, a benzothiazole ring, a quinoline ring, an isoquinoline ring, a quinoxaline ring, an acridine ring, a quinazoline ring, a cinnoline ring, and a phthalazine ring. In the present specification, a carbon atom constituting an aromatic ring is also referred to as an “aromatic carbon”.

Hereinafter, the present invention will be described in detail with reference to preferred embodiments thereof. However, the present invention is not limited to the embodiments and examples described below. The present invention may be optionally modified for implementation without departing from the scope of claims of the present invention and the scope of equivalents thereof.

### [Polyester Resin (X)]

The polyester resin (X) of the present invention is represented by the following general formula (1).

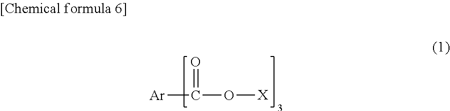

(in the formula,
   Ar represents an aromatic ring optionally having a substituent, and
   X each independently represents a monovalent organic group containing an aromatic ring,
   provided that one or more X out of three X contain at least two aromatic rings, and the total number of carbon atoms constituting these aromatic rings is 16 or more.)

The polyester resin (X) of the present invention is a trifunctional polyester resin in which three hydrogen atoms of an aromatic ring are each substituted with an organic oxycarbonyl group containing an aromatic ring, and is characterized in that one or more organic oxycarbonyl groups out of the three organic oxycarbonyl groups contain at least two aromatic rings, and the number of carbon atoms constituting these aromatic rings is 16 or more.

Such a polyester resin (X) of the present invention achieves a cured product exhibiting excellent dielectric properties in combination with the cross-linkable resin. Moreover, the polyester resin (X) of the present invention has favorable solubility in solvents and favorable solubility (compatibility) in other resins such as a cross-linkable resin, is excellent in handleability in the production of a printed wiring board and a semiconductor chip package, and easily achieves a cured product that has desired curing physical properties. Furthermore, the inventors have confirmed that the polyester resin (X) of the present invention can achieve a cured product that exhibits excellent dielectric properties in combination with the cross-linkable resin and is also excellent in heat resistance and smear removal in the formation of via holes.

### —Aromatic Ring Ar Optionally Having a Substituent—

In the formula (1), Ar represents an aromatic ring optionally having a substituent.

The aromatic ring in Ar may be any of a monocyclic aromatic ring and a condensed polycyclic aromatic ring in which two or more monocyclic aromatic rings are condensed, as described above. The aromatic ring may be either an aromatic carbocyclic ring or an aromatic heterocyclic ring.

From the viewpoint of achieving a cured product exhibiting even more excellent dielectric properties in combination with the cross-linkable resin, the aromatic ring in Ar is preferably an aromatic carbocycle ring. The number of carbon atoms of the aromatic carbocyclic ring is preferably 6 to 14, more preferably 6 to 10, and still more preferably 6 (i.e., a benzene ring).

The aromatic ring in Ar may have a substituent. Such substituents are as described above, but in particular, from the viewpoint of achieving a cured product exhibiting even more excellent dielectric properties in combination with the cross-linkable resin, one or more selected from a halogen atom, an alkyl group, and an aryl group are preferable, and one or more selected from a fluorine atom, an alkyl group of 1 to 6 carbon atoms, and an aryl group of 6 to 10 carbon atoms are more preferable.

Accordingly, in a preferred embodiment, the polyester resin (X) of the present invention is represented by the following general formula (1-1).

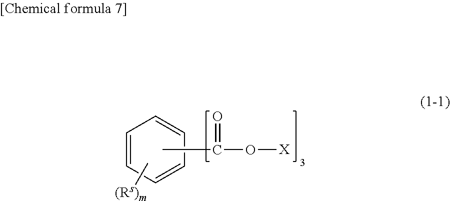

(in the formula,
   X each independently represents a monovalent organic group containing an aromatic ring,
   R^{s} each independently represents a substituent, and
   m represents an integer of 0 to 3,
   provided that one or more X out of the three X contain at least two aromatic rings, and the total number of carbon atoms constituting these aromatic rings is 16 or more.)

In the general formula (1-1), R^{s} each independently represents a substituent. Preferred types of substituents are as described above for the “aromatic ring” in Ar. That is, the substituent is preferably one or more selected from a halogen atom, an alkyl group, and an aryl group, and more preferably one or more selected from a fluorine atom, an alkyl group of 1 to 6 carbon atoms, and an aryl group of 6 to 10 carbon atoms.

In the general formula (1-1), m represents the number of substituents R^{s}, and represents an integer of 0 to 3.

### —Monovalent Organic Group X Containing Aromatic Ring—

In the general formula (1) and the general formula (1-1), X each independently represents a monovalent organic group containing an aromatic ring, provided that one or more X out of the three X contain at least two aromatic rings, and the total number of carbon atoms constituting these aromatic rings is 16 or more.

Although details of the X will be described later, from the viewpoint of achieving a cured product exhibiting excellent dielectric properties in combination with the cross-linkable resin, one or more X out of the three X is a monovalent organic group that contains at least two aromatic rings and in which the total number of carbon atoms constituting these aromatic rings is 16 or more. Hereinafter, the monovalent organic group is also referred to as a “monovalent organic group X′”. When one or more X out of the three X represents a monovalent organic group X′, a cured product exhibiting excellent dielectric properties can be achieved. In addition, favorable solubility in solvents and other resins is achieved, and a cured product excellent in heat resistance and smear removal in the formation of via holes can be achieved. Thus, this configuration is preferred. From the viewpoint of achieving better solubility in solvents and other resins, and also achieving a cured product that is excellent in heat resistance and smear removal in the formation of via holes in addition to exhibiting more excellent dielectric properties, it is preferable that two or more X out of the three X are a monovalent organic group X′, and more preferable that all the three X are a monovalent organic group X′. When the monovalent organic group represented by X contains at least two aromatic rings, the at least two aromatic rings may be the same as, or different from, each other.

The aromatic ring contained in the monovalent organic group represented by X may be either an aromatic carbocyclic ring or an aromatic heterocyclic ring. The aromatic carbocyclic ring and the aromatic heterocyclic ring are as described above. From the viewpoint of achieving a cured product exhibiting even more excellent dielectric properties in combination with the cross-linkable resin, the monovalent organic group represented by X preferably contains an aromatic carbocyclic ring as the aromatic ring. The number of carbon atoms in the aromatic carbocyclic ring is preferably 6 to 14.

The aromatic ring contained in the monovalent organic group represented by X may be either a monocyclic aromatic ring or a condensed polycyclic aromatic ring. The monocyclic aromatic ring and condensed polycyclic aromatic ring are as described above. From the viewpoint of achieving a cured product exhibiting even more excellent dielectric properties in combination with the cross-linkable resin, the monovalent organic group represented by X preferably contains a condensed polycyclic aromatic ring as the aromatic ring. Thus, in a preferred embodiment, the aromatic ring contained in the monovalent organic group represented by X contains a condensed polycyclic aromatic ring.

As mentioned above, one or more X out of the three X are the monovalent organic group X′ that contains at least two aromatic rings and in which the total number of carbon atoms constituting these aromatic rings is 16 or more. From the viewpoint of achieving favorable solubility in solvents and other resins in addition to achieving a cured product exhibiting excellent dielectric properties in combination with the cross-linkable resin and also of achieving a cured product excellent in heat resistance and smear removal in the formation of via holes, it is preferable that the monovalent organic group X′ contains a condensed polycyclic aromatic ring (preferably a condensed polycyclic aromatic carbocyclic ring) or contains three or more aromatic rings (preferably aromatic carbocyclic rings) so that the total number of carbon atoms constituting the aromatic rings is 16 or more. Thus, in a preferred embodiment, one or more X out of the three X contain a condensed polycyclic aromatic ring, more preferably a condensed polycyclic aromatic carbocyclic ring. Also, in a preferred embodiment, one or more X out of the three X contain three or more aromatic rings, more preferably three or more aromatic carbocyclic rings. Note that the total number of carbon atoms constituting the aromatic rings being 16 or more for the monovalent organic group X′ means that the total number of carbon atoms constituting the at least two aromatic rings contained in the monovalent organic group X′ is 16 or more. For example, when the monovalent organic group X′ contains one condensed polycyclic aromatic ring and one monocyclic aromatic ring, this refers to the total number (m1+m2) of the number m1 of carbon atoms constituting the one condensed polycyclic aromatic ring and the number m2 of carbon atoms constituting the one monocyclic aromatic ring. Furthermore, when the monovalent organic group X′ contains three aromatic rings, i.e., a first aromatic ring, a second aromatic ring, and a third aromatic ring, this refers to the total number (m1+m2+m3) of the number m1 of carbon atoms constituting the first aromatic ring, the number m2 of carbon atoms constituting the second aromatic ring, and the number m3 of carbon atoms constituting the third aromatic ring. The total number of such carbon atoms does not include the number of carbon atoms of substituents that the aromatic ring may have. In the monovalent organic group X′, the upper limit of the total number of carbon atoms constituting the aromatic rings is not particularly limited, and is preferably 50 or less, 40 or less, or 30 or less.

The aromatic ring contained in the monovalent organic group represented by X may have a substituent. Such substituents are as described above, and in particular, from the viewpoint of achieving a cured product exhibiting even more excellent dielectric properties in combination with the cross-linkable resin, one or more selected from a halogen atom, an alkyl group, and an aryl group are preferable, and one or more selected from a fluorine atom, an alkyl group of 1 to 6 carbon atoms, and an aryl group of 6 to 10 carbon atoms are more preferable.

The monovalent organic group represented by X is not particularly limited as long as it contains the aromatic ring described above, and is a group that contains at least a carbon atom as a skeletal atom, as described above. The monovalent organic group represented by X is preferably a monovalent group composed of 6 or more (preferably 10 or more, 12 or more or 14 or more, more preferably 16 or more, 18 or more or 20 or more, and, as the upper limit, preferably 100 or less, 80 or less, 60 or less, or 50 or less) skeletal atoms selected from a carbon atom, an oxygen atom, a nitrogen atom, and a sulfur atom. In particular, from the viewpoint of achieving a cured product exhibiting even more excellent dielectric properties in combination with the cross-linkable resin, it is particularly preferable that the monovalent organic group represented by X contains only carbon atoms as the skeletal atoms.

Accordingly, in a preferred embodiment, X represents a monovalent group containing an aromatic carbocyclic ring and containing only carbon atoms as the skeletal atoms, wherein the aromatic carbocyclic ring may have one or more of substituents selected from a fluorine atom, an alkyl group of 1 to 6 carbon atoms, and an aryl group of 6 to 10 carbon atoms. In a more preferred embodiment, X represents a monovalent group containing at least two aromatic carbocyclic rings and containing only carbon atoms as the skeletal atoms, wherein the aromatic carbocyclic rings may have one or more of substituents selected from a fluorine atom, an alkyl group of 1 to 6 carbon atoms, and an aryl group of 6 to 10 carbon atoms. Among these, from the viewpoint of achieving even better solubility in solvents and other resins and achieving a cured product excellent in heat resistance and smear removal in the formation of via holes in addition to excellent dielectric properties, for one or more X out of the three X (more preferably, two or more X and even more preferably all X), it is more preferable that one or more of the at least two aromatic carbocyclic rings are a condensed polycyclic aromatic carbocyclic ring, and it is more preferable that two or more out of the at least two aromatic carbocyclic rings are a condensed polycyclic aromatic carbocyclic ring. From a similar point of view, it is preferable for one or more X out of the three X (more preferably two or more X, even more preferably all X) to contain three or more aromatic carbocyclic rings as the at least two aromatic carbocyclic rings. A preferred value and a preferred range of the number of carbon atoms per aromatic carbocyclic ring that achieves a cured product exhibiting even more excellent dielectric properties in combination with the cross-linkable resin are as described above. In addition, a preferable range of the number of skeletal atoms constituting X is as described above.

From the viewpoint of achieving a cured product exhibiting excellent dielectric properties and also favorable heat resistance in combination with the cross-linkable resin, in the general formula (1) and the general formula (1-1), the oxygen atom bonded to X (the oxygen atom in the carbonyloxy group) is preferably bonded to the aromatic carbon of X, that is, the carbon atom constituting the aromatic ring described above.

In a preferred embodiment, X is each independently a monovalent organic group represented by the following general formula (2).

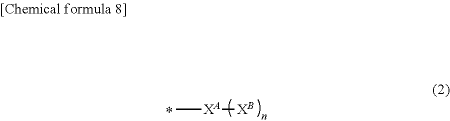

(in the formula,
   X^{A} represents a (1+n)-valent organic group containing at least one aromatic ring,
   X^{B} each independently represents a monovalent organic group containing at least one aromatic ring,
   n represents an integer of 0 to 6, and
   represents a bond to a carbonyloxy group,
   provided that, in one or more X out of three X, n represents an integer of 1 to 6, and the total number of carbon atoms constituting the aromatic rings contained in X is 16 or more.)

A monovalent organic group represented by the general formula (2) is composed of one X^{A} and n X^{B} bound to X^{A}. Here, n represents an integer of 0 to 6. X^{A} and X^{B} constituting the monovalent organic group represented by the general formula (2) will be described in detail later. From the viewpoint of achieving a cured product exhibiting excellent dielectric properties in combination with the cross-linkable resin, in one or more X out of three X, n represents an integer of 1 to 6, and the total number of carbon atoms constituting the aromatic rings contained in the X is 16 or more. When n represents an integer of 1 to 6 and the total number of carbon atoms constituting the aromatic rings contained in the X is 16 or more in one or more X out of the three X, a cured product exhibiting excellent dielectric properties can be achieved. In addition, favorable solubility in solvents and other resins is achieved, and a cured product excellent in heat resistance and smear removal in the formation of via holes can be achieved. Thus, this configuration is preferred. From the viewpoint of achieving better solubility in solvents and other resins and of achieving a cured product more excellent in heat resistance in addition to exhibiting more excellent dielectric properties, in 2 or more X out of the three X, it is preferable that n represents an integer of 1 to 6 and the total number of carbon atoms constituting the aromatic rings contained in the X is 16 or more. In all the three X, it is more preferable that n represents an integer of 1 to 6 and the total number of carbon atoms constituting the aromatic rings contained in the X is 16 or more.

### —X^{A}—

In the general formula (2), X^{A} represents a (1+n)-valent organic group containing at least one aromatic ring.

Preferred embodiments of the aromatic ring in X^{A} are as described for the “aromatic ring” contained in the monovalent organic group represented by X. That is, the aromatic ring in X^{A} may be either an aromatic carbocyclic ring or an aromatic heterocyclic ring. From the viewpoint of achieving a cured product exhibiting even more excellent dielectric properties in combination with the cross-linkable resin, the (1+n)-valent organic group represented by X^{A} preferably contains an aromatic carbocyclic ring as the aromatic ring. The number of carbon atoms in the aromatic carbocyclic ring is preferably 6 to 14. The aromatic ring in X^{A} may be either a monocyclic aromatic ring or a condensed polycyclic aromatic ring. From the viewpoint of achieving a cured product exhibiting even more excellent dielectric properties in combination with the cross-linkable resin, the (1+n)-valent organic group represented by X^{A} preferably contains a condensed polycyclic aromatic ring as the aromatic ring. Thus, in a preferred embodiment, the aromatic ring contained in the (1+n)-valent organic group represented by X^{A} contains an aromatic carbocyclic ring of 6 to 14 carbon atoms, more preferably a condensed polycyclic aromatic carbocyclic ring of 10 to 14 carbon atoms.

The aromatic ring in X^{A} may have a substituent. Preferred types of substituents are as described for the “aromatic ring” contained in the monovalent organic group represented by X. That is, the substituent is preferably one or more selected from a halogen atom, an alkyl group, and an aryl group, and more preferably one or more selected from a fluorine atom, an alkyl group of 1 to 6 carbon atoms, and an aryl group of 6 to 10 carbon atoms.

The (1+n)-valent organic group represented by X^{A} is not particularly limited as long as it contains the aromatic ring described above, and as described above, is a group that contains at least a carbon atom as a skeletal atom. The (1+n)-valent organic group represented by X^{A} is preferably a monovalent group composed of 6 or more (preferably 10 or more, 12 or more or 14 or more, and, as the upper limit, preferably 100 or less, 80 or less, 60 or less, or 50 or less) skeletal atoms selected from a carbon atom, an oxygen atom, a nitrogen atom, and a sulfur atom. In particular, from the viewpoint of achieving a cured product exhibiting even more excellent dielectric properties in combination with the cross-linkable resin, it is particularly preferable that the (1+n)-valent organic group represented by X^{A} contains only carbon atoms as the skeletal atoms.

Accordingly, in a preferred embodiment, X^{A} represents a monovalent group containing at least one aromatic carbocyclic ring and containing only carbon atoms as the skeletal atoms, wherein the aromatic carbocyclic ring may have one or more types of substituents selected from a fluorine atom, an alkyl group of 1 to 6 carbon atoms, and an aryl group of 6 to 10 carbon atoms. Among these, from the viewpoint of achieving a cured product excellent in heat resistance and smear removal in the formation of via holes in addition to excellent dielectric properties, it is more preferable that one or more out of the at least one aromatic carbocyclic ring is a condensed polycyclic aromatic carbocyclic ring. A preferred value and a preferred range of the number of carbon atoms per aromatic carbocyclic ring that achieves a cured product exhibiting even more excellent dielectric properties in combination with the cross-linkable resin are described above. In addition, a preferred range of the number of skeletal atoms constituting X^{A} is as described above.

From the viewpoint of achieving a cured product exhibiting excellent dielectric properties in combination with the cross-linkable resin and also having favorable heat resistance and smear removal in the formation of via holes, the monovalent organic group represented by X^{B} in the general formula (2) (detailed later) is preferably bonded to the aromatic carbon of X^{A}, that is, the carbon atoms constituting the aromatic rings described above.

In a particularly preferred embodiment, X^{A} is a (1+n)-valent organic group represented by the general formula (A).

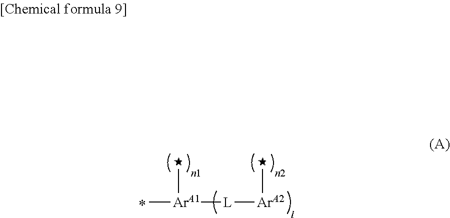

(in the formula,
   Ar^{A1} and Ar^{A2} each independently represent an aromatic ring optionally having a substituent,
   L represents a single bond or a divalent linking group,
   l 0 or 1,
   n1 and n2 are integers that satisfy n1+n2=n,
   * represents a bond to a carbonyloxy group, and
   a solid star mark represents a bond to X^{B}.)

The aromatic ring in Ar^{A1} and the aromatic ring in Ar^{A2} correspond to the “aromatic ring” previously described for X^{A}. When l is 0, X^{A} contains one aromatic ring. When l is 1, X^{A} contains two aromatic rings. Preferred types of these aromatic rings are as described above for X^{A}, including the types of substituents that they may have.

In the general formula (A), n1 and n2 are integers that indicate the number of bonds to X^{B} to be described later and satisfy n1+n2=n. Here, n is as described above. When the number of hydrogen atoms of Ar^{A1} that can be substituted is p, n1 represents an integer satisfying 0≤n1≤p, and when the number of hydrogen atoms of Ar^{A2} that can be substituted is q, n2 represents an integer satisfying 0 n2 q. The number p of hydrogen atoms of Ar^{A1} that can be substituted does not include a bonding site with a carbonyloxy group and a bonding site with L, and when Ar^{A1} has a substituent other than X^{B}, also does not include a bonding site with the substituent. The number q of hydrogen atoms in Ar^{A2} that can be substituted does not include a bonding site with L, and when Ar^{A2} has a substituent other than X^{B}, also does not include a bonding site with the substituent. For example, when l=0 and Ar^{A1} is a benzene ring having m substituents other than X^{B}, the number p of hydrogen atoms that can be substituted is (5−m). When l=0 and Ar^{A1} is a naphthalene ring having m substituents other than X^{B}, the number p of hydrogen atoms that can be substituted is (7−m). Also, for example, when 1=1 and Ar^{A1} is a benzene ring having m substituents other than X^{B}, the number p of hydrogen atoms that can be substituted is (4−m). When 1=1 and Ar^{A1} is a naphthalene ring having m substituents other than X^{B}, the number p of hydrogen atoms that can be substituted is (6−m). When Ar^{A2} is a benzene ring having m substituents other than X^{B}, the number p of hydrogen atoms that can be substituted is (5−m), and when Ar^{A2} is a naphthalene ring having m substituents other than X^{B}, the number p of hydrogen atoms that can be substituted is (7−m). In the polyester resin (X) of the present invention, it is preferable that X^{B} is bonded to the aromatic carbon of X^{A} so that the value of n1+n2, that is, the value of n satisfies the above-described range.

In the general formula (A), L represents a single bond or a divalent linking group. Examples of the divalent linking groups represented by L may include divalent organic groups composed of one or more (e.g., 1 to 50, 1 to 20, and 1 to 10) skeletal atoms selected from a carbon atom, an oxygen atom, a nitrogen atom, and a sulfur atom. Among these, a divalent aliphatic group optionally having a substituent is preferred. Therefore, in a preferred embodiment, L is a single bond or a divalent aliphatic group optionally having a substituent.

The divalent aliphatic group in L is as described above, and is preferably an alkylene group of 1 to 6 carbon atoms, a cycloalkylene group of 6 to 10 carbon atoms, or a divalent group composed of a combination of these. An alkylene group of 1 to 6 carbon atoms is more preferred.

The substituents which the divalent aliphatic group in L may have are as described above. Among these, the substituent is preferably at least one selected from a halogen atom, an alkyl group, and an aryl group, and more preferably at least one selected from a fluorine atom, an alkyl group of 1 to 6 carbon atoms, and an aryl group of 6 to 10 carbon atoms.

Examples of X^{A} represented by the general formula (A) particularly preferred from the viewpoint of achieving a cured product exhibiting even more excellent dielectric properties in combination with the cross-linkable resin may include the followings.

In a preferred embodiment, in the general formula (A),
l is 0,
Ar^{A1} represents an aromatic carbocyclic ring of 6 to 14 carbon atoms optionally having one or more types of substituents selected from a fluorine atom, an alkyl group of 1 to 6 carbon atoms, and an aryl group of 6 to 10 carbon atoms, and
n1 is an integer of 0 to 6 (preferably an integer of 1 to 6).

In a more preferred embodiment, in the general formula (A),
l is 0,
Ar^{A1} represents a condensed polycyclic aromatic carbocyclic ring of 10 to 14 carbon atoms optionally having one or more types of substituents selected from a fluorine atom, an alkyl group of 1 to 6 carbon atoms, and an aryl group of 6 to 10 carbon atoms, and
n1 is an integer of 0 to 6 (preferably an integer of 1 to 6).

In another preferred embodiment, in the general formula (A),
l is 1,
Ar^{A1} and Ar^{A2} each independently represent an aromatic carbocyclic ring of 6 to 14 carbon atoms optionally having one or more types of substituents selected from a fluorine atom, an alkyl group of 1 to 6 carbon atoms, and an aryl group of 6 to 10 carbon atoms,
L represents a single bond or an alkylene group of 1 to 6 carbon atoms optionally having one or more types of substituents selected from a fluorine atom, an alkyl group of 1 to 6 carbon atoms, and an aryl group of 6 to 10 carbon atoms, and
n1 and n2 are integers satisfying 0≤n1+n2≤6 (preferably 1≤n1+n2≤6).

The polyester resin (X) of the present invention has three X as shown in the general formula (1), and when the three X are each independently a monovalent organic group represented by the general formula (2), X^{A} may be the same as, or different from, each other. As mentioned above, one or more X out of the three X (preferably two or more X, more preferably all X) contain at least two aromatic rings, and the total number of carbon atoms constituting these aromatic rings is 16 or more. X^{A} may be determined as appropriate so that such conditions are met.

### —X^{B}—

In the general formula (2), X^{B} each independently represents a monovalent organic group containing at least one aromatic ring.

Preferred embodiments of the aromatic ring in X^{B} are as described for the “aromatic ring” contained in the monovalent organic group represented by X. That is, the aromatic ring in X^{B} may be either an aromatic carbocyclic ring or an aromatic heterocyclic ring. From the viewpoint of achieving a cured product exhibiting even more excellent dielectric properties in combination with the cross-linkable resin, it is preferable that the monovalent organic group represented by X^{B} contains an aromatic carbocyclic ring as the aromatic ring. The number of carbon atoms in the aromatic carbocyclic ring is preferably 6 to 14. The aromatic ring in X^{B} may be either a monocyclic aromatic ring or a condensed polycyclic aromatic ring. From the viewpoint of achieving favorable solubility in solvents and other resins in addition to achieving a cured product exhibiting even more excellent dielectric properties in combination with the cross-linkable resin, and also from the viewpoint of achieving a cured product exhibiting even more excellent heat resistance and smear removal in the formation of via holes, it is preferable that the monovalent organic group represented by X^{B} contains a condensed polycyclic aromatic ring as the aromatic ring. Thus, in a preferred embodiment, the aromatic ring contained in the monovalent organic group represented by X^{B} contains an aromatic carbocyclic ring of 6 to 14 carbon atoms, more preferably a condensed polycyclic aromatic carbocyclic ring of 10 to 14 carbon atoms.

The aromatic ring in X^{B} may have a substituent. Preferred types of the substituent are as described for the “aromatic ring” contained in the monovalent organic group represented by X. That is, the substituent is preferably one or more selected from a halogen atom, an alkyl group, and an aryl group, and more preferably one or more selected from a fluorine atom, an alkyl group of 1 to 6 carbon atoms, and an aryl group of 6 to 10 carbon atoms.

The monovalent organic group represented by X^{B} is not particularly limited as long as it contains the aromatic ring described above, and is a group that contains at least a carbon atom as a skeletal atom as described above. The monovalent organic group represented by X^{B} is preferably a monovalent group composed of 6 or more (preferably 7 or more, 8 or more, 9 or more or 10 or more, and, as the upper limit, preferably 50 or less, 30 or less, or 20 or less) skeletal atoms selected from a carbon atom, an oxygen atom, a nitrogen atom, and a sulfur atom. In particular, from the viewpoint of achieving a cured product exhibiting even more excellent dielectric properties in combination with the cross-linkable resin, it is particularly preferable that the monovalent organic group represented by X^{B} contains only carbon atoms as the skeletal atoms.

Accordingly, in a preferred embodiment, X^{B} represents a monovalent group containing at least one aromatic carbocyclic ring and containing only carbon atoms as the skeletal atoms, wherein the aromatic carbocyclic ring may have one or more types of substituents selected from a fluorine atom, an alkyl group of 1 to 6 carbon atoms, and an aryl group of 6 to 10 carbon atoms. Among these, from the viewpoint of achieving better solubility in solvents and other resins and achieving a cured product excellent in heat resistance and smear removal in the formation of via holes in addition to exhibiting more excellent dielectric properties, it is more preferable that one or more out of the at least one aromatic carbocyclic ring is a condensed polycyclic aromatic carbocyclic ring. A preferred value and a preferred range of the number of carbon atoms per aromatic carbocyclic ring that achieves a cured product exhibiting even more excellent dielectric properties in combination with the cross-linkable resin are described above. In addition, a preferred range of the number of skeletal atoms constituting X^{B} is as described above.

In a preferred embodiment, X^{B} is an aryl group of 6 to 14 carbon atoms optionally having a substituent or an arylalkyl group of 7 to 20 carbon atoms optionally having a substituent. Preferred types of substituents are as described above.

In a particularly preferred embodiment, X^{B} is each independently a monovalent organic group represented by the following general formula (B).

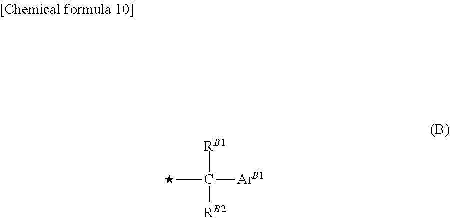

(in the formula,
   R^{B1} and R^{B2} each independently represent a hydrogen atom or an alkyl group,
   Ar^{B1} represents an aromatic ring optionally having a substituent, and
   a solid star mark represents a bond to X^{A}.)

The aromatic ring in Ar^{B1} corresponds to the “aromatic ring” previously described for X^{B}. When X^{B} is a monovalent organic group represented by the general formula (B), X^{B} contains one aromatic ring. Preferred types of such aromatic rings are as described above for X^{B}, including the types of substituents that they may have.

In the general formula (B), R^{B1} and R^{B2} each independently represent a hydrogen atom or an alkyl group. The number of carbon atoms of the alkyl group in R^{B1} and R^{B2} is preferably 1 to 6, more preferably 1 to 4, further preferably 1 or 2, and still further preferably 1 (i.e., a methyl group).

From the viewpoint of achieving favorable solubility in solvents and other resins in addition to achieving a cured product exhibiting even more excellent dielectric properties in combination with the cross-linkable resin, and also from the viewpoint of achieving a cured product exhibiting even more excellent heat resistance and smear removal in the formation of via holes, examples of the particularly preferred X^{B} represented by the general formula (B) are shown below.

In a preferred embodiment, in the general formula (B),
R^{B1} and R^{B2} are each independently a hydrogen atom or an alkyl group of 1 to 6 carbon atoms, and
Ar^{B1} represents an aromatic carbocyclic ring of 6 to 14 carbon atoms optionally having one or more types of substituents selected from a fluorine atom, an alkyl group of 1 to 6 carbon atoms, and an aryl group of 6 to 10 carbon atoms.

In a more preferred embodiment, in the general formula (B),
R^{B1} and R^{B2} are each independently a hydrogen atom or a methyl group, and
Ar^{B1} represents a condensed polycyclic aromatic carbocyclic ring of 10 to 14 carbon atoms optionally having one or more types of substituents selected from a fluorine atom, an alkyl group of 1 to 6 carbon atoms, and an aryl group of 6 to 10 carbon atoms.

The polyester resin (X) of the present invention has three X as shown in the general formula (1), and when the three X are each independently a monovalent organic group represented by the above-described general formula (2), X^{B} may be the same as, or different from, each other. As mentioned above, one or more X out of the three X (preferably two or more X, more preferably all X) contain at least two aromatic rings, and the total number of carbon atoms constituting these aromatic rings is 16 or more. X^{B} may be determined as appropriate so that such conditions are met.

As mentioned above, one or more X out of the three X (preferably two or more X, more preferably all X) are the monovalent organic group X′ that contains at least two aromatic rings and in which the total number of carbon atoms constituting these aromatic rings is 16 or more. From the viewpoint of further achieving the advantageous effects of the present invention, it is preferable that the monovalent organic group X′ contains a condensed polycyclic aromatic ring (preferably a condensed polycyclic aromatic carbocyclic ring) or three or more aromatic rings (preferably aromatic carbocyclic rings) so that the total number of carbon atoms constituting the aromatic rings is 16 or more. Particularly, from the viewpoint of achieving more better solubility in solvents and other resins in addition to achieving a cured product exhibiting more excellent dielectric properties in combination with the cross-linkable resin and also of achieving a cured product more excellent in heat resistance and smear removal in the formation of via holes, it is preferable that the three X are each independently a monovalent organic group represented by the above-described general formula (2), and, for one or more X (preferably 2 or more X, more preferably all X),
n represents an integer of 1 to 6, X^{A} contains a condensed polycyclic aromatic ring of 10 to 14 carbon atoms (preferably a condensed polycyclic aromatic carbocyclic ring), and X^{B} contains an aromatic ring of 6 to 14 carbon atoms (preferably an aromatic carbocyclic ring, specifically, a monocyclic aromatic carbocyclic ring or a condensed polycyclic aromatic carbocyclic ring), or
n represents an integer of 1 to 6, X^{A} contains one or two aromatic rings of 6 to 14 carbon atoms (preferably an aromatic carbocyclic ring, specifically, a monocyclic aromatic carbocyclic ring or a condensed polycyclic aromatic carbocyclic ring), X^{B} contains an aromatic ring of 6 to 14 carbon atoms (preferably an aromatic carbocyclic ring, specifically a monocyclic aromatic carbocyclic ring or a condensed polycyclic aromatic carbocyclic ring), and X^{A} and n X^{B} as a whole contain a total of three or more aromatic rings of 6 to 14 carbon atoms.

The preferred structures of X in the general formula (1) and the general formula (1-1) have been described above with reference to the general formula (2) and the general formulas (A) and (B). From the viewpoint of further achieving the advantageous effects of the present invention, the molecular weight of X is preferably 150 or more, more preferably 160 or more or 180 or more, still more preferably 200 or more, 210 or more or 220 or more. When the molecular weight of X is 200 or more while satisfying the above-mentioned preferred structure, a cured product exhibiting excellent dielectric properties can be achieved. In addition, favorable solubility in solvents and other resins is achieved, and a cured product excellent in heat resistance and smear removal in the formation of via holes can be achieved. Thus, this configuration is preferred. From the viewpoint of achieving favorable solubility in solvents and other resins in addition to achieving a cured product exhibiting even more excellent dielectric properties in combination with the cross-linkable resin, and also from the viewpoint of achieving a cured product exhibiting even more excellent heat resistance and smear removal in the formation of via holes, it is preferable that the molecular weight of one or more X out of the three X is 200 or more, it is more preferable that the molecular weight of two or more X out of the three X is 200 or more, and it is further preferable that the molecular weight of all the three X is 200 or more. The upper limit of the molecular weight of X is not particularly limited as long as it satisfies the above-described preferable structure, and may be, for example, 800 or less, 600 or less, 500 or less, 400 or less, or the like.

In the polyester resin (X) of the present invention, the equivalent weight of the oxycarbonyl group (active ester group equivalent weight) is preferably 200 g/eq. or more, more preferably 220 g/eq. or more, still more preferably 240 g/eq. or more, or 260 g/eq. or more. The upper limit of the active ester group equivalent weight may be, for example, 800 g/eq. or less, 700 g/eq. or less, 600 g/eq. or less, 500 g/eq. or less, 450 g/eq. or less, or 400 g/eq. or less, or the like.

An example of the procedure for synthesizing the polyester resin of the present invention will be described below.

In an embodiment, the polyester resin of the present invention is a condensation reaction product of:
(x1) an aromatic tricarboxylic acid compound or an aromatic tricarboxylic acid halide compound; and
(x2) an aromatic monohydroxy compound containing at least an aromatic monohydroxy compound that contains at least two aromatic rings and in which the total number of carbon atoms constituting these aromatic rings is 16 or more.

### —(x1) Aromatic Tricarboxylic Acid (Halide) Compound—

The component (x1) is an aromatic tricarboxylic acid compound or an aromatic tricarboxylic acid halide compound, and is represented by the following formula (x1).

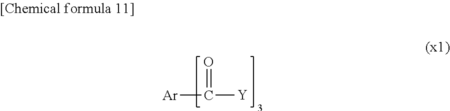

(in the formula, Ar is as described above and Y represents a hydroxyl group or a halogen atom.)

As the component (x1), any aromatic tricarboxylic acid (halide) compound may be used, depending on the Ar in the desired polyester resin. Preferred examples of Ar are as described above for the general formula (1). For example, when Ar in the desired polyester resin is a benzene ring optionally having a substituent, that is, when the polyester resin is represented by the general formula (1-1), the component (x1) used may be a benzene tricarboxylic acid (chloride) optionally having a substituent, for example, trimesic acid (chloride) optionally having a substituent. When Ar in the desired polyester resin is a naphthalene ring optionally having a substituent, the component (x1) used may be a naphthalene tricarboxylic acid (chloride) optionally having a substituent.

### —(x2) Aromatic Monohydroxy Compound—

The component (x2) is an aromatic monohydroxy compound containing at least an aromatic monohydroxy compound that contains at least two aromatic rings and in which the total number of carbon atoms constituting these aromatic rings is 16 or more, and is represented by the following formula (x2).

[Chemical formula 12]

X—OH (x2)
(in the formula, X is as described above.)

As the component (x2), any aromatic monohydroxy compound may be used depending on X in the desired polyester resin. Preferred examples of X are as described above for the general formula (1) and the general formula (1-1) with reference to the general formula (2) and the general formulas (A) and (B).

First, consider a case where X is a monovalent organic group (*—X^{A}—(X^{B})ₙ) represented by the general formula (2) and n is 1 or more.
(i) Examples of the component (x2), in which X^{A} is a (1+n)-valent organic group represented by the general formula (A) (in the formula, l=0, n1=1, and Ar^{A1} is a benzene ring optionally having a substituent) and X^{B} is an aryl group of 6 to 14 carbon atoms optionally having a substituent, may include a phenylphenol optionally having a substituent, a naphthylphenol optionally having a substituent, and an anthracenylphenol optionally having a substituent. Substituents, including preferred examples thereof, are as described above for the “aromatic ring” in X (the same applies to (ii)-(ix), hereinafter). In addition, the component having n1 (=n) of 2 to 5 may be applied by reading the terms “phenylphenol” and “naphthylphenol” in the above-mentioned definition as “di- to penta-(phenyl)phenol” and “di- to penta-(naphthyl)phenol”, respectively, for example.
(ii) Examples of the component (x2), in which X^{A} is a (1+n)-valent organic group represented by the general formula (A) (in the formula, l=0, n1=1, and Ar^{A1} is a naphthalene ring optionally having a substituent) and X^{B} is an aryl group of 6 to 14 carbon atoms optionally having a substituent, may include phenylnaphthol optionally having a substituent, naphthylnaphthol optionally having a substituent, and anthracenylnaphthol optionally having a substituent. In addition, the component having n1 (=n) of 2 to 6 may be applied by reading the terms “phenylnaphthol” and “naphthylnaphthol” in the above-mentioned definition as “di- to hexa-(phenyl)naphthol” and “di- to hexa-(naphthyl)naphthol”, respectively, for example.
(iii) Examples of the component (x2), in which X^{A} is a (1+n)-valent organic group represented by the general formula (A) (in the formula, l=0, n1=1, and Ar^{A1} is a benzene ring optionally having a substituent), and X^{B} is a monovalent organic group represented by the general formula (B) (in the formula, R^{B1} and R^{B2} are a hydrogen atom or a methyl group, and Ar^{B1} is a benzene ring optionally having a substituent), may include benzylphenol optionally having a substituent, and α-methylbenzylphenol optionally having a substituent. In addition, the component having n1 (=n) of 2 to 5 may be applied by reading the terms “benzylphenol” and “α-methylbenzylphenol” in the above-mentioned definition as “di- to penta-(benzyl)phenol” and “di- to penta-(α-methylbenzyl)phenol”, respectively.
(iv) Examples of the component, in which X^{A} is a (1+n)-valent organic group represented by the general formula (A) (in the formula, l=0, n1=1, and Ar^{A1} is a naphthalene ring optionally having a substituent), and X^{B} is a monovalent organic group represented by the general formula (B) (in the formula, R^{B1} and R^{B2} are a hydrogen atom or a methyl group, and Ar^{B1} is a benzene ring optionally having a substituent), may include benzylnaphthol optionally having a substituent, and α-methylbenzylnaphthol optionally having a substituent. In addition, the component having n1 (=n) of 2 to 6 may be applied by reading the terms “benzylnaphthol” and “α-methylbenzylphenol” in the above-mentioned definition as “di- to hexa-(benzyl)naphthol” and “di- to hexa-(α-methylbenzyl)naphthol”, respectively.
(v) Examples of the component (x2), in which X^{A} is a (1+n)-valent organic group represented by the general formula (A) (in the formula, l=0, n1=1, and Ar^{A1} is a naphthalene ring optionally having a substituent), and X^{B} is a monovalent organic group represented by the general formula (B) (in the formula, R^{B1} and R^{B2} are a hydrogen atom or a methyl group, and Ar^{B1} is a naphthalene ring optionally having a substituent), may include naphthylmethylnaphthol optionally having a substituent. In addition, the component having n1 (=n) of 2 to 6 may be applied by reading the term “naphthylmethylnaphthol” in the above-mentioned definition as “di- to hexa-(naphthylmethyl)naphthol”.
(vi) Examples of the component (x2), in which X^{A} is a (1+n)-valent organic group represented by the general formula (A) (in the formula, 1=1, n1+n2=1, Ar^{A1} and Ar^{A2} are a benzene ring optionally having a substituent, and L is a single bond), and X^{B} is an aryl group of 6 to 14 carbon atoms optionally having a substituent, may include monohydroxy monophenylbiphenyl optionally having a substituent, monohydroxy mononaphthylbiphenyl optionally having a substituent, and monohydroxy monoanthracenylbiphenyl optionally having a substituent. In addition, the component having n1+n2 (=n) of 2 to 6 may be applied by reading the terms “monohydroxy monophenylbiphenyl” and “monohydroxy mononaphthylbiphenyl” in the above-mentioned definition as “monohydroxy-di- to hexa-(phenyl)-biphenyl” and “monohydroxy-di- to hexa-(naphthyl)-biphenyl”, respectively, for example.
(vii) Examples of the component, in which X^{A} is a (1+n)-valent organic group represented by the general formula (A) (in the formula, 1=1, n1+n2=1, Ar^{A1} and Ar^{A2} are a benzene ring optionally having a substituent, and L is a single bond), and X^{B} thereof is a monovalent organic group represented by the general formula (B) (in the formula, R^{B1} and R^{B2} are a hydrogen atom or a methyl group, and Ar^{B1} is a benzene ring optionally having a substituent), may include monohydroxy monobenzylbiphenyl optionally having a substituent, and monohydroxy mono(α-methylbenzyl)biphenyl optionally having a substituent. In addition, the component having n1+n2 (=n) of 2 to 6 may be applied by reading the terms “monohydroxy monobenzylbiphenyl” and “monohydroxy mono(α-methylbenzyl)biphenyl” in the above-mentioned definition as “monohydroxy-di- to hexa-(benzyl)-biphenyl, and “monohydroxy-di- to hexa-(α-methylbenzyl)-biphenyl”, respectively.

Next, consider a case where X is a monovalent organic group represented by the general formula (2) and n is 0.
(viii) As the component (x2) in which X^{A} is a monovalent organic group represented by the general formula (A) (in the formula, l=0, n1=0, and Ar^{A1} is a benzene ring optionally having a substituent), phenol optionally having a substituent may be used.
(ix) As the component (x2) in which X^{A} is a monovalent organic group represented by the general formula (A) (in the formula, l=0, n1=0, and Ar^{A1} is a naphthalene ring optionally having a substituent), naphthol optionally having a substituent may be used.

The component (x2) used in the production of the polyester resin (X) of the present invention is an aromatic monohydroxy compound containing at least an aromatic monohydroxy compound that contains at least two aromatic rings and in which the total number of carbon atoms constituting these aromatic rings is 16 or more. As the component (x2), for example, an aromatic monohydroxy compound containing only one aromatic ring may be used as in (viii) and (ix) described above. However, in this case, it is essential to use an aromatic monohydroxy compound that contains at least two aromatic rings and in which the total number of carbon atoms constituting these aromatic rings is 16 or more, in relation to the (i) to (vii) described above in order to achieve the advantageous effects of the present invention.

The content of the aromatic monohydroxy compound that contains at least two aromatic rings and in which the total number of carbon atoms constituting these aromatic rings is 16 or more in the component (x2) is preferably 20 mol % or more, 30 mol % or more or 40 mol % or more, more preferably 60 mol % or more, still more preferably 70 mol % or more, 80 mol % or more, or 90 mol % or more, when the total content of the component (x2) is 100 mol %. The upper limit of the content is not particularly limited, and may be 100 mol %. When the content of the aromatic monohydroxy compound that contains at least two aromatic rings and in which the total number of carbon atoms constituting these aromatic rings is 16 or more in the component (x2) falls within the above-mentioned range, it is easy to satisfy the characteristics of the polyester resin (X) of the present invention, provided that one or more X out of three X are a monovalent organic group containing at least two aromatic rings and the total number of carbon atoms constituting these aromatic rings is 16 or more.

From the viewpoint of further achieving the advantageous effects of the present invention, the hydroxyl equivalent of the aromatic monohydroxy compound (x2) is preferably 150 g/eq. or more, more preferably 160 g/eq. or more, or 180 g/eq. or more, still more preferably 200 g/eq. or more, 210 g/eq. or more, or 220 g/eq. or more. The upper limit of the hydroxyl equivalent is not particularly limited, and is, for example, 800 g/eq. or less, 600 g/eq. or less, 500 g/eq. or less, 400 g/eq or less. or the like.

When an aromatic monohydroxy compound (HO—X^{A}—(X^{B})ₙ) that contains X^{A} and n X^{B} like the (i) to (vii) described above is used as the component (x2), a commercially available product may be used, or the compound may be synthesized by a reaction between an aromatic monohydroxy compound (HO—X^{A}) and an X^{B} precursor compound (for example, an aromatic vinyl compound such as vinylbenzene or vinylnaphthalene; an aromatic haloalkyl compound such as chloromethylbenzene or chloromethylnaphthalene; and an aromatic alcohol compound such as benzyl alcohol), where a hydrogen atom of an aromatic ring of the aromatic monohydroxy compound (HO—X^{A}) is replaced with X^{B}. The number of X^{B} in the aromatic monohydroxy compound (HO—X^{A}—(X^{B})ₙ), i.e., the value of n, can be adjusted by changing the quantitative ratio of the aromatic monohydroxy compound (HO—X^{A}) to the X^{B} precursor compound.

The aromatic monohydroxy compound (HO—X^{A}—(X^{B})ₙ) that contains X^{A} and n X^{B} like the (i) to (vii) described above may be present as a mixture of aromatic monohydroxy compounds with different n values. Even in such a case, it has been confirmed that the advantageous effects of the present invention can be obtained when the average value of n as a mixture is more than 0 and 6 or less. Therefore, when a mixture of aromatic monohydroxy compounds with different n values is used as the aromatic monohydroxy compound, the above-described general formula (2) may be applied by reading “n represents an integer of 0 to 6, provided that in one or more X out of three X, n represents an integer of 1 to 6” as “n represents an average value of the number of X^{B} and represents a number satisfying 0<n≤6”. Similarly, the general formula (A) described above may be applied by reading “n1 and n2 are integers satisfying n1+n2=n” as “n1 and n2 are numbers satisfying n1+n2=n”. From the viewpoint of further achieving the advantageous effects of the present invention, the average value of n is preferably 0.4 or more, more preferably 0.6 or more, more preferably 0.7 or more, 0.8 or more, 0.9 or more or 1.0 or more, and the upper limit of the average value is 6 or less.

The condensation reaction between the components (x1) and (x2) may be proceeded in a solvent-free system without using a solvent or in an organic solvent system using an organic solvent. Examples of the organic solvent used in the condensation reaction may include: a ketone-based solvent such as acetone, methyl ethyl ketone, methyl isobutyl ketone, and cyclohexanone; an acetic ester-based solvent such as ethyl acetate, butyl acetate, cellosolve acetate, propylene glycol monomethyl ether acetate, and carbitol acetate; a carbitol-based solvent such as cellosolve and butyl carbitol; an aromatic hydrocarbon solvent such as toluene and xylene; and an amide-based solvent such as N,N-dimethylformamide, N,N-dimethylacetamide, and N-methyl-2-pyrrolidone. As the organic solvent, one type thereof may be solely used, and two or more types thereof may also be used in combination.

A base may be used in the condensation reaction. Examples of the base may include: an alkali metal hydroxide such as sodium hydroxide (caustic soda) and potassium hydroxide; and tertiary amines such as triethylamine, pyridine, and N,N-dimethyl-4-aminopyridine (DMAP). As the base, one type thereof may be solely used, and two or more types thereof may also be used in combination.

A condensation agent and/or a phase transfer catalyst may also be used in the condensation reaction. As these agents, any conventionally known agents that can be used in the esterification reaction may be used.

The reaction temperature in the condensation reaction is not particularly limited as long as the condensation reaction is proceeded. For example, the reaction temperature may be in a range of 0 to 80° C. Furthermore, the reaction time in the condensation reaction is not particularly limited as long as the desired structure of the polyester resin is achieved. For example, the reaction time may be in a range of 30 minutes to 8 hours.

The polyester resin may be purified after the condensation reaction. For example, a purification step such as washing with water or microfiltration may be performed after the condensation reaction to remove by-product salts and excessive starting materials from the system. Specifically, after the condensation reaction, water is added in an amount necessary for dissolving the by-product salts, and an aqueous layer obtained by static liquid separation is discarded. Furthermore, an acid is added as needed for neutralization, and washing with water is repeated. Then, a dehydration process is performed using a chemical agent or by azeotropic distillation, followed by microfiltration to remove impurities for purification. Subsequently, as necessary, the organic solvent is removed by distillation to obtain the polyester resin. The organic solvent may not be completely removed and the remaining organic solvent may be used as it is as a solvent for the resin composition.

The polyester resin of the present invention achieves a cured product exhibiting excellent dielectric properties in combination with the cross-linkable resin. The polyester resin (X) of the present invention also has favorable solubility in solvents and solubility (compatibility) with other resins such as the cross-linkable resin, and is easy to handle when producing printed wiring boards and semiconductor chip packages, making it easy to produce a cured product with the desired cured properties. Furthermore, the polyester resin (X) of the present invention exhibits excellent dielectric properties in combination with the cross-linkable resin and also can achieve a cured product excellent in heat resistance and smear removal in the formation of via holes. Thus, in a preferred embodiment, the polyester resin of the present invention can be suitably used as a resin cross-linking agent.

### [Resin Composition]

The polyester resin (X) of the present invention can be used to produce a resin composition. The present invention also provides such a resin composition.

The resin composition of the present invention contains the polyester resin (X) and the cross-linkable resin (Y), and is characterized in that the polyester resin (X) is the polyester resin of the present invention, i.e., the trifunctional polyester resin represented by the above-mentioned general formula (1) or general formula (1-1).

Details of the polyester resin (X), including preferred examples of the aromatic ring represented by Ar and the monovalent organic group represented by X, and preferred embodiments of the general formulas, are as described above in the section [Polyester resin (X)].

In the resin composition of the present invention, the type of the cross-linkable resin (Y) is not particularly limited as long as it can be crosslinked in combination with the polyester resin (X). The cross-linkable resin (Y) is preferably one or more types selected from the group consisting of a thermosetting resin and a radically polymerizable resin from the viewpoint of achieving a cured product exhibiting excellent dielectric properties and also achieving a cured product having favorable heat resistance in combination with the polyester resin (X).

As the thermosetting resin and the radically polymerizable resin, known resins used in forming an insulating layer for printed wiring boards or semiconductor chip packages may be used. Hereinafter, a thermosetting resin and a radically polymerizable resin that can be used as the cross-linkable resin (Y) will be described.

Examples of the thermosetting resin may include an epoxy resin, a benzocyclobutene resin, an epoxy acrylate resin, a urethane acrylate resin, a urethane resin, a cyanate resin, a polyimide resin, a benzoxazine resin, an unsaturated polyester resin, a phenol resin, a melamine resin, a silicone resin, and a phenoxy resin. As the thermosetting resin, one type thereof may be solely used, and two or more types thereof may also be used in combination. Among these, the cross-linkable resin (Y) preferably includes an epoxy resin from the viewpoint of exhibiting favorable compatibility with the polyester resin (X) when preparing a resin composition in combination with the polyester resin (X) and also achieving excellent dielectric properties and heat resistance after curing.

The type of the epoxy resin is not particularly limited as long as it has one or more (preferably two or more) epoxy groups within one molecule. Examples of the epoxy resin may include a bisphenol A type epoxy resin, a bisphenol F type epoxy resin, a bisphenol S type epoxy resin, a bisphenol AF type epoxy resin, a phenol novolac type epoxy resin, a tert-butyl-catechol type epoxy resin, a naphthol type epoxy resin, a naphthalene type epoxy resin, a naphthylene ether type epoxy resin, a glycidyl amine type epoxy resin, a glycidyl ester type epoxy resin, a cresol novolac type epoxy resin, a biphenyl type epoxy resin, a phenol aralkyl type epoxy resin, a biphenyl aralkyl type epoxy resin, a fluorene-skeleton type epoxy resin, a dicyclopentadiene type epoxy resin, an anthracene type epoxy resin, a linear aliphatic epoxy resin, an epoxy resin having a butadiene structure, an alicyclic epoxy resin, a heterocyclic epoxy resin, a spirocyclic epoxy resin, a cyclohexanedimethanol type epoxy resin, a trimethylol type epoxy resin, and a halogenated epoxy resin. According to the resin composition of the present invention containing the polyester resin (X), it is possible to exhibit favorable compatibility when preparing a resin composition and also achieve excellent dielectric properties and heat resistance after curing, regardless of the type of the epoxy resin.

The epoxy resin may be classified into epoxy resins in a liquid state at a temperature of 20° C. (hereinafter referred to as a “liquid epoxy resin”) and epoxy resins in a solid state at a temperature of 20° C. (hereinafter referred to as a “solid epoxy resin”), and the resin composition of the present invention may contain only a liquid epoxy resin as the cross-linkable resin (Y), may contain only a solid epoxy resin, or may contain a combination of a liquid epoxy resin and a solid epoxy resin. When a combination of a liquid epoxy resin and a solid epoxy resin is contained, the blending ratio (liquid:solid) may be in the range of 20:1 to 1:20 by mass ratio (preferably 10:1 to 1:10, more preferably 3:1 to 1:3).

The equivalent weight of the epoxy group of the epoxy resin is preferably 50 g/eq. to 2000 g/eq., more preferably 60 g/eq. to 1000 g/eq., and further preferably 80 g/eq. to 500 g/eq. The equivalent weight of the epoxy group is a mass of the epoxy resin containing one equivalent of epoxy groups and may be measured according to JIS K7236.

The weight-average molecular weight (Mw) of the epoxy resin is preferably 100 to 5,000, more preferably 250 to 3,000, and further preferably 400 to 1,500. Mw of the epoxy resin may be measured as a polystyrene equivalent value by a GPC method.

The type of the radically polymerizable resin is not particularly limited as long as it has one or more (preferably two or more) radically polymerizable unsaturated groups within one molecule. Examples of the radically polymerizable resin may include resins containing, as a radically polymerizable unsaturated group, one or more types selected from a maleimide group, a vinyl group, an allyl group, a styryl group, a vinylphenyl group, an acryloyl group, a methacryloyl group, a fumaroyl group, and a maleoyl group. Among these, the cross-linkable resin (Y) preferably contains one or more types selected from a maleimide resin, a (meth)acrylic resin, and a styryl resin, from the viewpoint of exhibiting favorable compatibility with the polyester resin (X) when preparing a resin composition in combination with the polyester resin (X) and also achieving excellent dielectric properties and heat resistance after curing.

The type of the maleimide resin is not particularly limited as long as it has one or more (preferably two or more) maleimide groups (2,5-dihydro-2,5-dioxo-1H-pyrrol-1-yl group) within one molecule. Examples of the maleimide resin may include a maleimide resin containing an aliphatic skeleton of 36 carbon atoms derived from a dimer diamine, such as “BMI-3000J”, “BMI-5000”, “BMI-1400”, “BMI-1500”, “BMI-1700”, and “BMI-689” (all manufactured by Designer Molecules Inc.); a maleimide resin containing an indane skeleton described in Journal of Technical Disclosure No. 2020-500211 published by Japan Institute for Promoting Invention and Innovation; and a maleimide resin containing an aromatic ring skeleton directly bonded to a nitrogen atom of a maleimide group such as “MIR-3000-70MT” (manufactured by Nippon Kayaku Co., Ltd.), “BMI-4000” (manufactured by Daiwa Fine Chemicals Co., Ltd.), and “BMI-80” (manufactured by K—I Chemical Industry CO., LTD.).

The type of the (meth)acrylic resin is not particularly limited as long as it has one or more (preferably two or more) (meth)acryloyl groups within one molecule, and may be a monomer or an oligomer. Herein, the term “(meth)acryloyl group” is a generic term for an acryloyl group and a methacryloyl group. Examples of the methacrylic resin in addition to a (meth)acrylate monomer may include (meth)acrylic resins such as “A-DOG” (manufactured by Shin-Nakamura Chemical Co., Ltd.), “DCP-A” (manufactured by Kyoeisha Chemical Co., Ltd.), “NPDGA”, “FM-400”, “R-687”, “THE-330”, “PET-30”, and “DPHA” (all manufactured by Nippon Kayaku Co., Ltd.).

The type of the styryl resin is not particularly limited as long as it has one or more (preferably two or more) styryl groups or vinylphenyl groups within one molecule, and may be a monomer or an oligomer. Examples of the styryl resin in addition to a styrene monomer may include styryl resins such as “OPE-2St”, “OPE-2St 1200”, and “OPE-2St 2200” (all manufactured by Mitsubishi Gas Chemical Co., Inc.).

The resin composition of the present invention may contain, as the cross-linkable resin (Y), only a thermosetting resin, only a radically polymerizable resin, or a combination of a thermosetting resin and a radically polymerizable resin.

From the viewpoint of achieving a cured product having excellent heat resistance in addition to exhibiting excellent dielectric properties in combination with the polyester resin (X), the content of the cross-linkable resin (Y) in the resin composition is preferably 5% by mass or more, more preferably 10% by mass or more, still more preferably 12% by mass or more, 14% by mass or more, or 15% by mass or more, when the resin component in the resin composition is defined as 100% by mass. The upper limit of the content is not particularly limited, and may be determined according to the characteristics required for the resin composition, for example, 60% by mass or less, 55% by mass or less, 50% by mass or less, 45% by mass or less, or the like. In the present invention, the “resin components” for the resin composition refers to components excluding an inorganic filler, which will be described later, among the nonvolatile components constituting the resin composition.

In the resin composition of the present invention, the mass ratio ((X)/(Y)) of the polyester resin (X) to the cross-linkable resin (Y) is preferably 0.5 or more, more preferably 0.6 or more, 0.8 or more or 1 or more, still more preferably 1.1 or more, 1.2 or more, 1.3 or more, or 1.4 or more from the viewpoint of further achieving the advantageous effects of the present invention. The upper limit of the mass ratio ((X)/(Y)) may be, for example, 10 or less, 8 or less, 6 or less, 5 or less, or the like. Thus, in an embodiment, the mass ratio ((X)/(Y)) of the polyester resin (X) to the cross-linkable resin (Y) is 0.5 to 10.

The resin composition of the present invention may further include an inorganic filler. When the resin composition includes the inorganic filler, the coefficient of linear thermal expansion and the dielectric loss tangent can be reduced.

Examples of the inorganic filler may include silica, alumina, barium sulfate, talc, clay, mica powder, aluminum hydroxide, magnesium hydroxide, calcium carbonate, magnesium carbonate, magnesium oxide, boron nitride, aluminum borate, barium titanate, strontium titanate, calcium titanate, magnesium titanate, bismuth titanate, titanium oxide, barium zirconate, and calcium zirconate. Among these, silica is preferable. Examples of the silica may include amorphous silica, fused silica, crystalline silica, synthetic silica, and hollow silica. As silica, spherical silica is preferable. As the inorganic filler, one type thereof may be solely used, and two or more types thereof may also be used in combination. Examples of commercially available products of the inorganic filler may include “UFP-30” (manufactured by Denka Co., Ltd.); “YC100C”, “YA050C”, “YA050C-MJE”, “YA010C”, “SC2500SQ”, “SO-C4”, “SO-C2”, “SO-C1”, and “SC-C2” (all manufactured by Admatechs Co., Ltd.); and “Silfil NSS-3N”, “Silfil NSS-4N”, and “Silfil NSS-5N” (manufactured by Tokuyama Corp.).

The average particle diameter of the inorganic filler is preferably 5 μm or less, more preferably 2 μm or less, and further preferably 1 μm or less from the viewpoint of making the surface of the cured product (insulating layer) low roughness and facilitating fine wiring formation. The lower limit of the average particle diameter is not particularly limited, and may be, for example, 0.01 μm or more, 0.02 μm or more, 0.03 μm or more, or the like. The average particle diameter of the inorganic filler may be measured by a laser diffraction scattering method based on the Mie scattering theory. Specifically, the average particle diameter may be measured by creating a particle size distribution of the inorganic filler on a volume basis by a laser diffraction scattering particle size distribution analyzer, and using the obtained median diameter as the average particle diameter. As the measurement sample, an inorganic filler dispersed in water by ultrasonic waves may be preferably used. The laser diffraction scattering particle size distribution measuring apparatus to be used may include LA-950 manufactured by HORIBA, Ltd. or the like.

The inorganic filler is preferably one obtained by performing a surface treatment with a surfaced treating agent, such as an aminosilane-based coupling agent, an ureidosilane-based coupling agent, an epoxy-silane-based coupling agent, a mercaptosilane-based coupling agent, a vinylsilane-based coupling agent, a styrylsilane-based coupling agent, an acrylate-silane-based coupling agent, an isocyanate-silane-based coupling agent, a sulfide silane-based coupling agent, an organosilazane compound, or a titanate-based coupling agent, to improve its moisture resistance and dispersibility.

When the resin composition of the present invention includes an inorganic filler, the content of the inorganic filler in the resin composition may be determined according to the properties required for the resin composition. When the nonvolatile component in the resin composition is defined as 100% by mass, for example, the content thereof is 5% by mass or more, 10% by mass or more, preferably 30% by mass or more, more preferably 40% by mass or more, and further preferably 50% by mass or more. The upper limit of the content of the inorganic filler is not particularly limited, and may be, for example, 90% by mass or less, 85% by mass or less, 80% by mass or less, or the like.

The resin composition of the present invention may further contain a resin cross-linking agent other than the polyester resin (X).

Examples of resin cross-linking agents other than the polyester resin (X) may include a phenol-based curing agent, such as “TD2090” and “TD2131” (manufactured by DIC Corp.), “MEH-7600”, “MEH-7851”, and “MEH-8000H” (manufactured by Meiwa Plastic Industries, Ltd.), “NHN”, “CBN”, “GPH-65”, and “GPH-103” (manufactured by Nippon Kayaku Co., Ltd.), “SN170”, “SN180”, “SN190”, “SN475”, “SN485”, “SN495”, “SN375”, and “SN395” (manufactured by Nippon Steel Chemical & Materials Co., Ltd.), and “LA7052”, “LA7054”, “LA3018”, and “LA1356” (manufactured by DIC Corp.); a benzoxazine-based cross-linking agent such as “F-a” and “P-d” (manufactured by Shikoku Chemicals Corp.), and “HFB2006M” (manufactured by Showa Highpolymer Co., Ltd.); an acid anhydride cross-linking agent such as methylhexahydrophthalic anhydride, methylnadic anhydride, and hydrogenated methylnadic anhydride; a cyanate ester-based cross-linking agent such as PT30, PT60, and BA230S75 (manufactured by LONZA K.K.); and a benzoxazine-based cross-linking agent.

When the resin composition of the present invention includes a resin cross-linking agent, the content of the resin cross-linking agent in the resin composition may be determined according to the properties required for the resin composition. When the resin component in the resin composition is defined as 100% by mass, the content thereof is preferably 40% by mass or less, more preferably 20% by mass or less, and further preferably 10% by mass or less, and the lower limit thereof is 0.01% by mass or more, 0.05% by mass or more, 0.1% by mass or more, or the like.

The resin composition of the present invention may further contain a cross-linking accelerator. By containing the cross-linking accelerator, the cross-linking time and the cross-linking temperature can be efficiently adjusted.

Examples of the cross-linking accelerator may include an organophosphine compound such as “TPP”, “TPP-K”, “TPP-S”, and “TPTP-S” (manufactured by Hokko Chemical Industry Co., Ltd.); an imidazole compound such as “Cuazole 2MZ”, “2E4MZ”, “Cl1Z”, “C11Z—CN”, “Cl1Z-CNS”, “Cl1Z-A”, “2MZ-OK”, “2MA-OK”, and “2PHZ” (manufactured by Shikoku Chemicals Corp.); an amine adduct compound such as Novacure (manufactured by Asahi Kasei Corp.) and Fijicure (manufactured by Fuji Kasei Kogyo Co., Ltd.); an amine compound such as 1,8-diazabicyclo[5,4,0]undecene-7,4-dimethylaminopyridine, benzyldimethylamine, 2,4,6-tris(dimethylaminomethyl)phenol, and 4-dimethylaminopyridine; and organometallic complexes or organometallic salts of such as cobalt, copper, zinc, iron, nickel, manganese, tin, and the like.

When the resin composition of the present invention includes the cross-linking accelerator, the content of the cross-linking accelerator in the resin composition may be determined according to the properties required for the resin composition. When the resin component in the resin composition is defined as 100% by mass, the content thereof is preferably 5% by mass or less, more preferably 4% by mass or less, and further preferably 3% by mass or less, and the lower limit thereof is 0.01% by mass or more, 0.05% by mass or more, 0.1% by mass or more, or the like.

The resin composition of the present invention may further contain other additives. Examples of the additive may include an organic filler such as rubber particles; a photocationic polymerization initiator and a photo acid generator, such as a sulfonium salt-based agent, an iodonium salt-based agent, and a nonionic-based agent; a photosensitizer such as a naphthoquinone diazide compound; a radical polymerization initiator such as a peroxide-based radical polymerization initiator and an azo-based radical polymerization initiator; a thermoplastic resin such as a phenoxy resin, a polyvinyl acetal resin, a polysulfone resin, a polyether sulfone resin, a polyphenylene ether resin, a polyether ether ketone resin, and a polyester resin; an organometallic compound such as an organocopper compound, an organozinc compound, and an organocobalt compound; a colorant such as phthalocyanine blue, phthalocyanine green, iodine green, diazo yellow, crystal violet, titanium oxide, and carbon black; a polymerization inhibitor such as hydroquinone, catechol, pyrogallol, and phenothiazine; a leveling agent such as a silicone-based leveling agent and an acrylic polymer-based leveling agent; a thickener such as bentone and montmorillonite; a defoamer such as a silicon-based defoamer, an acrylic-based defoamer, a fluorine-based defoamer, and a vinyl-based defoamer; a UV absorber such as a benzotriazole-based UV absorber; an adhesion improver such as urea silane; an adhesion imparting agent such as a triazole-based adhesion imparting agent, a tetrazole-based adhesion imparting agent, and a triazine-based adhesion imparting agent; an antioxidant such as a hindered phenol-based antioxidant; a fluorescent brightener such as a stilbene derivative; a surfactant such as a fluorine-based surfactant and a silicone-based surfactant; a flame retardant such as a phosphorus-based flame retardant (e.g., a phosphate ester compound, a phosphazene compound, a phosphinic acid compound, and red phosphorus), a nitrogen-based flame retardant (e.g., melamine sulfate), a halogen-based flame retardant, and an inorganic flame retardant (e.g., antimony trioxide); a dispersant such as a phosphate-based dispersant, a polyoxyalkylene-based dispersant, an acetylene-based dispersant, a silicone-based dispersant, an anionic dispersant, and a cationic dispersant; and a stabilizer such as a borate-based stabilizer, a titanate-based stabilizer, an aluminate-based stabilizer, a zirconate-based stabilizer, an isocyanate-based stabilizer, a carboxylic acid-based stabilizer, and a carboxylic anhydride-based stabilizer. The content of such additives may be determined according to the properties required for the resin composition.

The resin composition of the present invention may further contain an organic solvent as a volatile component. Examples of the organic solvent may include: a ketone-based solvent such as acetone, methyl ethyl ketone, methyl isobutyl ketone, and cyclohexanone; an ester-based solvent such as methyl acetate, ethyl acetate, butyl acetate, isobutyl acetate, isoamyl acetate, methyl propionate, ethyl propionate, and γ-butyrolactone; an ether-based solvent such as tetrahydropyran, tetrahydrofuran, 1,4-dioxane, diethyl ether, diisopropyl ether, dibutyl ether, and diphenyl ether; an alcohol-based solvent such as methanol, ethanol, propanol, butanol, and ethylene glycol; an ether ester-based solvent such as 2-ethoxyethyl acetate, propylene glycol monomethyl ether acetate, diethylene glycol monoethyl ether acetate, ethyl diglycol acetate, γ-butyrolactone, and methyl methoxypropionate; an ester alcohol-based solvent such as methyl lactate, ethyl lactate, and methyl 2-hydroxyisobutyrate; an ether alcohol-based solvent such as 2-methoxypropanol, 2-methoxyethanol, 2-ethoxyethanol, propylene glycol monomethyl ether, and diethylene glycol monobutyl ether (butyl carbitol); an amide-based solvent such as N,N-dimethylformamide, N,N-dimethylacetamide, and N-methyl-2-pyrrolidone; a sulfoxide-based solvent such as dimethyl sulfoxide; a nitrile-based solvent such as acetonitrile and propionitrile; an aliphatic hydrocarbon-based solvent such as hexane, cyclopentane, cyclohexane, and methylcyclohexane; and an aromatic hydrocarbon-based solvent such as benzene, toluene, xylene, ethylbenzene, and trimethylbenzene. As the organic solvent, one type thereof may be solely used, and two or more types thereof may also be used in combination.

When the resin composition of the present invention contains an organic solvent, the content of the organic solvent in the resin composition may be determined according to the properties required for the resin composition. When all the components in the resin composition are defined as 100% by mass, for example, the content thereof may be set to 60% by mass or less, 40% by mass or less, 30% by mass or less, 20% by mass or less, 15% by mass or less, 10% by mass or less, or the like.

The resin composition of the present invention may be prepared by appropriately mixing the necessary components among the above-mentioned components, and kneading or mixing by a kneading means such as a three-roll mill, a ball mill, a bead mill, a sand mill, or the like, or a stirring means such as a super mixer, a planetary mixer, or the like as necessary.

The resin composition of the present invention, which includes the polyester resin (X) and the cross-linkable resin (Y) in combination, can have excellent compatibility during preparation and can achieve the cured product exhibiting excellent dielectric properties and favorable heat resistance after curing.

In an embodiment, the cured product of the resin composition of the present invention has a characteristic of having a low dielectric constant (Dk). For example, the dielectric constant (Dk) of the cured product of the resin composition of the present invention can be preferably 3.2 or less, 3.1 or less, 3.0 or less, 2.9 or less, or 2.8 or less, when measured at 5.8 GHz and 23° C. as described in the section of [Dielectric properties] below.

In an embodiment, the cured product of the resin composition of the present invention has a characteristic of having a low dielectric loss tangent (Df). For example, the dielectric loss tangent (Df) of the cured product of the resin composition of the present invention can be preferably 0.01 or less, 0.008 or less, 0.006 or less, 0.005 or less, 0.004 or less, or 0.003 or less, when measured at 5.8 GHz and 23° C. as described in the section of [Dielectric properties] below.

In an embodiment, the cured product of the resin composition of the present invention is characterized by high heat resistance. For example, when measured using a dynamic viscoelastometer under measurement conditions of a load of 200 mN and a heating rate of 2° C./min as described in the [Heat resistance] section below, the glass transition temperature (Tg) may preferably be 110° C. or higher, 120° C. or higher, 125° C. or higher, 130° C. or higher, 135° C. or higher, 140° C. or higher, 145° C. or higher, or 150° C. or higher.

As described above, the resin composition of the present invention is excellent in compatibility during preparation, exhibits excellent dielectric properties after curing, and can achieve a cured product that is excellent in heat resistance and smear removal in the formation of via holes. Thus, the resin composition of the present invention can be suitably used as a resin composition for forming an insulation layer of a printed wiring board (a resin composition for an insulation layer of a printed wiring board), and more suitably used as a resin composition for forming an interlayer insulation layer of a printed wiring board (a resin composition for an interlayer insulation layer of a printed wiring board). The resin composition of the present invention can also be suitably used when a printed wiring board is a component-embedded circuit board. The resin composition of the present invention can also be suitably used as a resin composition for sealing a semiconductor chip (a resin composition for semiconductor sealing). The resin composition of the present invention can be suitably used as a resin composition for a redistribution forming layer as an insulation layer for forming the redistribution layer (a resin composition for a redistribution forming layer). The resin composition of the present invention can also be used in a wide range of applications where a resin composition is required, such as a sheet-like laminated material such as a resin sheet or a prepreg, a solder resist, an underfill material, a die bonding material, a hole-filling resin, and a component-embedding resin.

### [Sheet-Like Laminated Material (Resin Sheet and Prepreg)]

The resin composition of the present invention can also be used as is. However, it may be used in the form of a sheet-like laminated material including the resin composition.

As the sheet-like laminated material, the following resin sheet and prepreg are preferable.

In an embodiment, the resin sheet includes a support and a layer of the resin composition disposed on the support (hereinafter, simply referred to as “resin composition layer”), and the resin composition layer is formed of the resin composition of the present invention.

The thickness of the resin composition layer varies in preferable values depending on applications and may be appropriately determined according to the applications. For example, the thickness of the resin composition layer is preferably 200 μm or less, more preferably 150 μm or less, 120 μm or less, 100 μm or less, 80 μm or less, 60 μm or less, or 50 μm or less, from the viewpoint of reducing the thickness of the printed wiring board or the semiconductor chip package. Although the lower limit of the thickness of the resin composition layer is not particularly limited, it can be usually 1 μm or more, 5 μm or more, or the like.

Examples of the support may include a thermoplastic resin film, a metal foil, and a release paper. A thermoplastic resin film and a metal foil are preferable. Therefore, in a preferred embodiment, the support is a thermoplastic resin film or a metal foil.

When a thermoplastic resin film is used as the support, examples of the thermoplastic resin may include a polyester such as a polyethylene terephthalate (PET) and a polyethylene naphthalate (PEN), a polycarbonate (PC), an acrylic resin such as a polymethyl methacrylate (PMMA), a cyclic polyolefin, a triacetyl cellulose (TAC), a polyether sulfide (PES), a polyether ketone, and a polyimide. Among these, a polyethylene terephthalate and a polyethylene naphthalate are preferable, and an inexpensive polyethylene terephthalate is particularly preferable.

In a case where a metal foil is used as the support, examples of the metal foil may include a copper foil and an aluminum foil. A copper foil is preferable. As the copper foil, a foil made of a single metal of copper may be used, or a foil made of an alloy of copper and different metal (e.g., tin, chromium, silver, magnesium, nickel, zirconium, silicon, titanium, etc.) may be used.

The support may be subjected to a matte treatment, a corona treatment, and an antistatic treatment on the surface to be bonded to the resin composition layer. Furthermore, as the support, a support with release layer having a release layer on the surface to be bonded to the resin composition layer may be used. A release agent used in the release layer of the support with release layer may be one or more types of release agents selected from the group consisting of an alkyd resin, a polyolefin resin, a urethane resin, and a silicone resin. A commercially available product may be used as the support with release layer. Examples thereof may include “SK-1”, “AL-5”, and “AL-7” manufactured by Lintec Corp., which are a PET film with a release layer including an alkyd resin-based release agent as a main component, “LUMIRROR T60” manufactured by Toray Industries, Inc., “PUREX” manufactured by Teijin Ltd., and “UNIPEEL” manufactured by Unitika Ltd.

The thickness of the support is not particularly limited. However, the thickness is preferably in a range of 5 m to 75 μm, more preferably in a range of 10 μm to 60 μm. Note that, in a case where the support with release layer is used, the thickness of the support with release layer as a whole preferably falls within the above-mentioned range.

When a metal foil is used as the support, a metal foil with supporting substrate, in which a peelable supporting substrate is bonded to a thin metal foil, may also be used. In an embodiment, the metal foil with supporting substrate includes a supporting substrate, a release layer disposed on the supporting substrate, and a metal foil disposed on the release layer. In a case where a metal foil with supporting substrate is used as the support, the resin composition layer is disposed on the metal foil.

In the metal foil with supporting substrate, a material of the supporting substrate is not particularly limited. However, examples of the material may include a copper foil, an aluminum foil, a stainless-steel foil, a titanium foil, and a copper alloy foil. In a case where a copper foil is used as the supporting substrate, an electrolytic copper foil or a rolled copper foil may be used. Furthermore, the release layer is not particularly limited as long as the metal foil can be released from the supporting substrate. Examples of the release layer may include: an alloy layer of elements selected from the group consisting of Cr, Ni, Co, Fe, Mo, Ti, W, and P; and an organic film.

In the metal foil with supporting substrate, preferable examples of a material of the metal foil may include a copper foil and a copper alloy foil.

In the metal foil with supporting substrate, the thickness of the supporting substrate is not particularly limited. However, the thickness is preferably in a range of 10 μm to 150 μm, more preferably in a range of 10 μm to 100 μm. Furthermore, the thickness of the metal foil may be, for example, in a range of 0.1 μm to 10 μm.

In an embodiment, the resin sheet may further include an optional layer as necessary. Examples of such an optional layer may include a protective film disposed on the surface of the resin composition layer, which is not bonded to the support (i.e., the surface on the opposite side to the support). The thickness of the protective film is not particularly limited. However, the thickness is, for example, 1 μm to 40 μm. Laminating the protective film can prevent the surface of the resin composition layer from being dusted or scratched.

The resin sheet can be produced by, for example, using the liquid resin composition as it is or preparing a resin varnish by dissolving the resin composition in an organic solvent, applying the resin composition onto the support using a die coater or the like, and then drying the resin composition to form a resin composition layer. The polyester resin (X) of the present invention is excellent in solubility in solvents and solubility (compatibility) with other resins such as the cross-linkable resin, and therefore the resin sheet that achieves a desired effect can be easily prepared by using the resin composition of the present invention.

Examples of the organic solvent may include the same organic solvents described as the component of the resin composition. As the organic solvent, one type thereof may be solely used, and two or more types thereof may also be used in combination.

The drying may be performed by a known method such as heating or blowing with hot air. Although drying conditions are not particularly limited, the drying is performed so that the content of the organic solvent in the resin composition layer is reduced to 10% by mass or less, preferably 5% by mass or less. The drying conditions vary depending on the boiling point of the organic solvent in the resin composition or the resin varnish. For example, in a case where the resin composition or the resin varnish including 30% by mass to 60% by mass of an organic solvent is used, the resin composition layer can be formed by drying the resin composition or the resin varnish at 50° C. to 150° C. for 3 minutes to 10 minutes.

The resin sheet can be wound into a roll and stored. In a case where the resin sheet has a protective film, the resin sheet can be used by peeling off the protective film.

In an embodiment, the prepreg is formed by impregnating a sheet-like fiber substrate with the resin composition of the present invention.

The sheet-like fiber substrate used for the prepreg is not particularly limited. A material commonly used as a substrate for prepreg, such as glass cloth, aramid nonwoven fabric, or liquid crystal polymer nonwoven fabric, can be used. From the viewpoint of reducing the thickness of the printed wiring board or the semiconductor chip package, the thickness of the sheet-like fiber substrate is preferably 50 μm or less, more preferably 40 μm or less, further preferably 30 μm or less, and particularly preferably 20 μm or less. The lower limit of the thickness of the sheet-like fiber substrate is not particularly limited. However, it is usually 10 μm or more.

The prepreg can be produced by a known method such as a hot melt method or a solvent method.

The thickness of the prepreg can be in the same range as the resin composition layer in the resin sheet described above.

The sheet-like laminated material of the present invention can be suitably used for forming an insulation layer of the printed wiring board (for an insulation layer of printed wiring board), and more suitably used for forming an interlayer insulation layer of the printed wiring board (for an interlayer insulation layer of printed wiring board). The sheet-like laminated material of the present invention can also be suitably used for sealing a semiconductor chip (for sealing semiconductor). The sheet-like laminated material can be suitably used for a redistribution forming layer as an insulation layer for forming a redistribution layer.

### [Printed Wiring Board]

The printed wiring board of the present invention includes the insulation layer formed of the cured product of the resin composition of the present invention.

The printed wiring board can be produced by, for example, a method including the following steps (I) and (II) using the above-mentioned resin sheet:
(I) a step of laminating a resin sheet on an inner layer substrate so that a resin composition layer of the resin sheet is bonded to the inner layer substrate; and
(II) a step of curing (e.g., thermally curing) the resin composition layer to form an insulation layer.

The “inner layer substrate” used in the step (I) is a member that serves as a substrate of the printed wiring board. Examples of the inner layer substrate may include a glass epoxy substrate, a metal substrate, a polyester substrate, a polyimide substrate, a BT resin substrate, and a thermosetting polyphenylene ether substrate. Furthermore, such a substrate may have a conductor layer on one or both surfaces, and this conductor layer may be patterned. The inner layer substrate having the conductor layer (circuit) formed on one or both surfaces of the substrate is sometimes referred to as an “inner layer circuit substrate”. Furthermore, an intermediate product on which the insulation layer and/or the conductor layer are to be formed in the production of the printed wiring board is also included in the “inner layer substrate” as defined in the present invention. In a case where the printed wiring board is a component-embedded circuit board, an inner layer substrate having components embedded therein may be used.

The lamination of the inner layer substrate and the resin sheet can be performed by, for example, thermocompression bonding of the resin sheet to the inner layer substrate carried out from the support side. Examples of a member for use in performing the thermocompression bonding of the resin sheet to the inner layer substrate (hereinafter also referred to as “thermocompression bonding member”) may include a heated metal plate (a SUS head plate, etc.) and a heated metal roll (a SUS roll). Note that the thermocompression bonding member may be directly pressed onto the resin sheet or may be pressed through an elastic material such as heat-resistant rubber so that the resin sheet sufficiently follows the uneven surface of the inner layer substrate.

The lamination of the inner layer substrate and the resin sheet may be performed by a vacuum lamination method. In the vacuum lamination method, the thermocompression bonding temperature is preferably in a range of 60° C. to 160° C., more preferably 80° C. to 140° C., the thermocompression bonding pressure is preferably in a range of 0.098 MPa to 1.77 MPa, more preferably 0.29 MPa to 1.47 MPa, and the thermocompression bonding time is preferably in a range of 20 seconds to 400 seconds, more preferably 30 seconds to 300 seconds. The lamination can be performed under a reduced pressure condition, preferably, at a pressure of 26.7 hPa or less.

The lamination can be performed with a commercially available vacuum laminator. Examples of the commercially available vacuum laminator may include a vacuum pressure laminator manufactured by Meiki Co., Ltd., and a vacuum applicator and a batch type vacuum pressure laminator manufactured by Nikko-Materials Co., Ltd.

After the lamination, the laminated resin sheet may be subjected to a smoothing treatment by, for example, pressing the laminated resin sheet from the support side with the thermocompression bonding member under normal pressure (atmospheric pressure). Pressing conditions for the smoothing treatment can be the same as the conditions for the thermocompression bonding used for the lamination described above. The smoothing treatment can be performed with a commercially available laminator. Note that the lamination and the smoothing treatment may be performed successively using the commercially available vacuum laminator described above.

The support may be removed between the step (I) and the step (II) or may be removed after the step (II). Note that, in a case where a metal foil is used as the support, the conductor layer may be formed using the metal foil without peeling off the support. Furthermore, in a case where a metal foil with supporting substrate is used as the support, the supporting substrate (and the release layer) is simply peeled off. Then, a conductor layer can be formed using the metal foil.

In the step (II), the resin composition layer is cured (e.g., thermally cured) to form an insulation layer formed of a cured product of the resin composition. Curing conditions for the resin composition layer are not particularly limited, and the conditions usually employed for forming an insulation layer of the printed wiring board may be used.

Thermal curing conditions for the resin composition layer vary depending on the type of the resin composition and the like. However, for example, in an embodiment, the curing temperature is preferably 120° C. to 250° C., more preferably 150° C. to 240° C., and further preferably 180° C. to 230° C. The curing time can be preferably 5 minutes to 240 minutes, more preferably 10 minutes to 150 minutes, and further preferably 15 minutes to 120 minutes.

Before being thermally cured, the resin composition layer may be preheated at a temperature lower than the curing temperature. For example, before being thermally cured, the resin composition layer may be preheated at a temperature of 50° C. to 120° C., preferably 60° C. to 115° C., more preferably 70° C. to 110° C. for 5 minutes or more, preferably 5 minutes to 150 minutes, more preferably 15 minutes to 120 minutes, and further preferably 15 minutes to 100 minutes.

In the production of the printed wiring board, a step (III) of perforating the insulation layer, a step (IV) of subjecting the insulation layer to a roughening treatment, and a step (V) of forming a conductor layer may be further performed. These steps (III) to (V) may be performed according to various methods known to those skilled in the art used in the production of the printed wiring board. Note that, in a case where a support is removed after the step (II), the support may be removed between the step (II) and the step (III), between the step (III) and the step (IV), or between the step (IV) and the step (V). Furthermore, if necessary, the steps (I) to (V) of forming the insulation layer and the conductor layer may be repeated to form a multilayer wiring board.

In another embodiment, the printed wiring board of the present invention can be produced using the prepreg described above. A production method is basically the same as the method using the resin sheet.

The step (III) is a step of perforating the insulation layer, whereby a hole such as a via hole or a through hole can be formed in the insulation layer. The step (III) may be performed using, for example, a drill, laser, plasma, or the like, depending on the composition and the like of the resin composition used for forming the insulation layer. The size and shape of the hole may be appropriately determined according to a design of the printed wiring board.

The step (IV) is a step of subjecting the insulation layer to a roughening treatment. Usually, removal of smear (desmear) is also performed in this step (IV). The insulation layer formed using the resin composition including the polyester resin (X) of the present invention can achieve favorable smear removal. A procedure and conditions for the roughening treatment are not particularly limited, and a known procedure and conditions that are commonly used for forming an insulation layer of a printed wiring board can be employed. For example, the roughening treatment of the insulation layer can be performed by carrying out a swelling treatment with a swelling liquid, a roughening treatment with an oxidizing agent, and a neutralizing treatment with a neutralizing liquid, in this order.

The swelling liquid used for the roughening treatment is not particularly limited. However, examples thereof may include an alkaline solution and a surfactant solution. Of these, an alkaline solution is preferable. As the alkaline solution, a sodium hydroxide solution and a potassium hydroxide solution are more preferable. Examples of a commercially available swelling liquid may include “SWELLING DIP SECURIGANTH P” and “SWELLING DIP SECURIGANTH SBU” manufactured by Atotech Japan K.K. The condition of the swelling treatment with the swelling liquid is not particularly limited. However, the swelling treatment can be performed by, for example, immersing the insulation layer in the swelling liquid at 30° C. to 90° C. for 1 minute to 20 minutes. From the viewpoint of restraining swelling of the resin in the insulation layer to an appropriate level, it is preferable to immerse the insulation layer in the swelling liquid at 40° C. to 80° C. for 5 minutes to 15 minutes.

The oxidizing agent used in the roughening treatment is not particularly limited. However, examples of the oxidizing agent may include an alkaline permanganate solution in which potassium permanganate or sodium permanganate is dissolved in an aqueous solution of sodium hydroxide. The roughening treatment with the oxidizing agent such as the alkaline permanganate solution is preferably performed by immersing the insulation layer in the oxidizing agent solution heated to 60° C. to 100° C. for 10 minutes to 30 minutes. Furthermore, a concentration of the permanganate in the alkaline permanganate solution is preferably 5% by mass to 10% by mass. Examples of a commercially available oxidizing agent may include an alkaline permanganate solution such as “CONCENTRATE COMPACT CP” or “DOSING SOLUTION SECURIGANS P” manufactured by Atotech Japan K.K.

Furthermore, the neutralizing liquid used for the roughening treatment is preferably an acidic aqueous solution. Examples of a commercially available neutralizing liquid may include “REDUCTION SOLUTION SECURIGANTH P” manufactured by Atotech Japan K.K.

The treatment with the neutralizing liquid can be performed by immersing the treated surface, which has been subjected to the roughening treatment with the oxidizing agent, in the neutralizing liquid at 30° C. to 80° C. for 5 minutes to 30 minutes. From the viewpoint of workability and the like, a method of immersing the object, which has been subjected to the roughening treatment with the oxidizing agent, in the neutralizing liquid at 40° C. to 70° C. for 5 minutes to 20 minutes is preferable.

The step (V) is a step of forming a conductor layer, whereby the conductor layer is formed on the insulation layer. A conductor material used for the conductor layer is not particularly limited. In a preferred embodiment, the conductor layer includes one or more types of metal selected from the group consisting of gold, platinum, palladium, silver, copper, aluminum, cobalt, chromium, zinc, nickel, titanium, tungsten, iron, tin, and indium. The conductor layer may be a single metal layer or an alloy layer. Examples of the alloy layer may include a layer formed of an alloy of two or more different metal selected from the above-mentioned group (e.g., a nickel-chromium alloy, a copper-nickel alloy, and a copper-titanium alloy). Of these, from the viewpoint of versatility, costs, easiness of patterning, and the like for forming the conductor layer, a single metal layer of chromium, nickel, titanium, aluminum, zinc, gold, palladium, silver, or copper, or an alloy layer of a nickel-chromium alloy, a copper-nickel alloy, or a copper-titanium alloy is preferable. A single metal layer of chromium, nickel, titanium, aluminum, zinc, gold, palladium, silver, or copper, or an alloy layer of a nickel-chromium alloy is more preferable, and a single metal layer of copper is still more preferable.

The conductor layer may have a single layer structure or a multi-layer structure in which two or more single metal layers or alloy layers formed of different types of metal or alloys are laminated. In a case where the conductor layer has the multilayer structure, a layer in contact with the insulation layer is preferably a single metal layer of chromium, zinc, or titanium, or an alloy layer of a nickel-chromium alloy.

The thickness of the conductor layer is generally 3 μm to 35 μm, preferably 5 μm to 30 μm, depending on a desired design of the printed wiring board.

In an embodiment, the conductor layer may be formed by plating. For example, the conductor layer having a desired wiring pattern can be formed by plating the surface of the insulation layer by a conventionally known technique such as a semi-additive method or a full-additive method. From the viewpoint of simplicity in the production, the conductor layer is preferably formed by the semi-additive method. An example of forming the conductor layer by the semi-additive method will be described below.

First, a plating seed layer is formed on the surface of the insulation layer by electroless plating. Next, a mask pattern is formed on the plating seed layer thus formed to expose a part of the plating seed layer corresponding to a desired wiring pattern. After a metal layer is formed on the exposed plating seed layer by electroplating, the mask pattern is removed. Subsequently, the unnecessary plating seed layer is removed by etching or the like to form the conductor layer having a desired wiring pattern.

In another embodiment, the conductor layer may be formed using a metal foil. In a case where the metal foil is used to form the conductor layer, the step (V) is performed preferably between the step (I) and the step (II). For example, after the step (I), the support is removed, and then the metal foil is laminated on the exposed surface of the resin composition layer. Lamination of the resin composition layer and the metal foil may be performed by a vacuum lamination method. Lamination conditions may be the same as the conditions described for the step (I). Next, the step (II) is performed to form the insulation layer. Subsequently, the conductor layer having a desired wiring pattern can be formed using the metal foil on the insulation layer by a conventional known technique such as a subtractive method or a modified semi-additive method.

The metal foil can be produced by a known method such as, for example, an electrolysis method or a rolling method. Examples of a commercially available metal foil may include HLP foil and JXUT-III foil manufactured by JX Nippon Mining & Metals Corp. and 3EC-III foil and TP-III foil manufactured by Mitsui Mining & Smelting Co., Ltd.

Alternatively, as described above, in the case where the metal foil or the metal foil with supporting substrate is used as the support for the resin sheet, the conductor layer may be formed using the metal foil.

### [Semiconductor Chip Package]

The semiconductor chip package of the present invention includes a sealing layer formed of the cured product of the resin composition of the present invention. Alternatively, as described above, the semiconductor chip package of the present invention may include an insulation layer for forming a redistribution layer (redistribution forming layer), which is formed of the cured product of the resin composition of the present invention.

The semiconductor chip package can be produced, for example, using the resin composition or the resin sheet of the present invention by a method including the following steps (1) to (6). The resin composition or the resin sheet of the present invention may be used to form a sealing layer in the step (3) or a redistribution forming layer in the step (5). An example of forming the sealing layer and/or the redistribution forming layer using the resin composition or the resin sheet will be described below. However, a technique for forming the sealing layer and the redistribution forming layer of the semiconductor chip packages is known, and those skilled in the art can produce the semiconductor package according to the known technique using the resin composition or the resin sheet of the present invention:
(1) a step of laminating a temporary fixing film on a substrate;
(2) a step of temporarily fixing a semiconductor chip on the temporary fixing film;
(3) a step of forming a sealing layer on the semiconductor chip;
(4) a step of peeling off the substrate and the temporary fixing film from the semiconductor chip;
(5) a step of forming a redistribution forming layer as an insulation layer on the surface of the semiconductor chip from which the substrate and the temporary fixing film have been peeled off; and
(6) a step of forming a redistribution layer as a conductor layer on the redistribution forming layer

### —Step (1)—

A material used for the substrate is not particularly limited. Examples of the substrate may include: a silicon wafer; a glass wafer; a glass substrate; a metal substrate of such as copper, titanium, stainless steel, and steel plate cold commercial (SPCC); a substrate prepared by impregnating a glass fiber with an epoxy resin or the like, followed by a thermal curing treatment (e.g., FR-4 substrate); and a substrate made of a bismaleimide triazine resin (BT resin).

A material of the temporary fixing film is not particularly limited as long as the temporary fixing film can temporarily fix the semiconductor chip and can be peeled off from the semiconductor chip in the step (4). A commercially available product can be used as the temporary fixing film. Examples of the commercially available product thereof may include REVALPHA manufactured by Nitto Denko Corp.

### —Step (2)—

The temporal fixing of the semiconductor chip can be performed using a known device such as a flip chip bonder or a die bonder. Arrangement layout and the installation number of the semiconductor chips can be appropriately determined according to the shape and size of the temporary fixing film, the production number of the semiconductor packages of interest, and the like. For example, the semiconductor chips can be arranged in a matrix form of multiple rows and multiple columns and temporarily fixed.

### —Step (3)—

The resin composition layer of the resin sheet of the present invention is laminated on the semiconductor chip, or the resin composition of the present invention is applied onto the semiconductor chip and then cured (e.g., thermally cured), to form a sealing layer.

For example, the lamination of the semiconductor chip and the resin sheet can be performed by removing the protective film from the resin sheet and performing thermocompression bonding of the resin sheet to the semiconductor chip from the support side. Examples of a member for performing the thermocompression bonding of the resin sheet to the semiconductor chip (hereinafter also referred to as “thermocompression bonding member”) may include a heated metal plate (a SUS head plate, etc.) and a heated metal roll (a SUS roll). Further, it is preferable that, instead of directly pressing the thermocompression bonding member onto the resin sheet, the thermocompression bonding member is pressed onto the resin sheet through an elastic material such as heat-resistant rubber so that the resin sheet sufficiently follows the uneven surface of the semiconductor chip. The lamination of the semiconductor chip and the resin sheet may be performed by a vacuum lamination method, and conditions for the lamination is the same as the lamination conditions described in relation to the method for producing the printed wiring board. Preferable ranges thereof are also the same.

After the lamination, the resin composition is thermally cured to form a sealing layer. Thermal curing conditions are the same as the thermal curing conditions described in relation to the method for producing the printed wiring board.

The support of the resin sheet may be peeled off after the resin sheet is laminated onto the semiconductor chip and thermally cured, or the support may be peeled off before the resin sheet is laminated onto the semiconductor chip.

In a case where the resin composition of the present invention is applied to form a sealing layer, conditions for the application is the same as the application conditions for forming the resin composition layer described in relation to the resin sheet of the present invention. Preferable ranges thereof are also the same.

### —Step (4)—

A method for peeling off the substrate and the temporary fixing film can be appropriately changed according to the material of the temporary fixing film and the like. Examples of the method may include a method in which the temporary fixing film is peeled off by heating and foaming (or expanding) the temporary fixing film and a method in which the temporary fixing film is peeled off by irradiating the film with ultraviolet rays from the substrate side and thereby reducing the adhesive force of the temporary fixing film.

In the method in which the temporary fixing film is peeled off by heating and foaming (or expanding) the temporary fixing film, heating conditions are usually 100 to 250° C. for 1 to 90 seconds or 5 to 15 minutes. Furthermore, in the method in which the temporary fixing film is peeled off by irradiating the film with ultraviolet rays from the substrate side and thereby reducing the adhesive force of the temporary fixing film, an irradiation dose of ultraviolet rays is usually 10 mJ/cm² to 1000 mJ/cm².

### —Step (5)—

A material for forming the redistribution forming layer (insulation layer) is not particularly limited as long as insulation properties are exhibited when the redistribution forming layer (insulation layer) is formed. From the viewpoint of easiness in the production of the semiconductor chip package, a ultraviolet curable resin or a thermosetting resin is preferable. The redistribution forming layer may be formed using the resin composition or the resin sheet of the present invention.

After the redistribution forming layer is formed, a via hole may be formed in the redistribution forming layer for interlayer connection between the semiconductor chip and a conductor layer described below. The via hole may be formed by a known method depending on the material of the redistribution forming layer. The redistribution forming layer formed using the resin composition containing the polyester resin (X) of the present invention can achieve favorable smear removal in the formation of via holes.
Step (6)—

The formation of the conductor layer on the redistribution forming layer may be performed in the same manner as the step (V) described in relation to the method for producing the printed wiring board. Note that the step (5) and the step (6) may be repeated to alternately laminate (build up) the conductor layers (redistribution layers) and the redistribution forming layers (insulation layers).

In the production of the semiconductor chip package, a step (7) of forming a solder resist layer on the conductor layer (redistribution layer), a step (8) of forming a bump, and a step (9) of dicing a plurality of semiconductor chip packages into individual semiconductor chip packages, thereby separating them as individual pieces, may be further performed. These steps may be performed according to various methods known to those skilled in the art used in the production of the semiconductor chip package.

When the sealing layer and/or the redistribution forming layer are formed by using the resin composition or the resin sheet of the present invention that achieves a cured product exhibiting excellent dielectric properties and favorable heat resistance, regardless of whether the semiconductor package is a Fan-In type package or a Fan-Out type package, it is possible to achieve the semiconductor chip package. In an embodiment, the semiconductor chip package of the present invention is a Fan-Out type package. The resin composition or the resin sheet of the present invention can be applied for both Fan-Out type panel level packaging (FOPLP) and Fan-Out type wafer level packaging (FOWLP). In an embodiment, the semiconductor package of the present invention is a product of the Fan-Out type panel level packaging (FOPLP). In another embodiment, the semiconductor package of the present invention is a product of the Fan-Out type wafer level packaging (FOWLP).

### [Semiconductor Device]

The semiconductor device of the present invention includes a layer formed of the cured product of the resin composition layer of the present invention. The semiconductor device of the present invention can be produced by using the printed wiring board or the semiconductor chip package of the present invention.

Examples of the semiconductor device may include various semiconductor devices used in electrical products (e.g., a computer, a mobile phone, a digital camera, a television, etc.) and vehicles (e.g., a motorcycle, an automobile, a train, a ship, an aircraft, etc.).

### EXAMPLES

The present invention will be described below more specifically by Examples. The present invention is not particularly limited to these Examples.

### <Example 1> Synthesis of Trifunctional Polyester Resin (1)

### (1) Synthesis of Aromatic Monohydroxy Compound (1)

In a 1-liter four-necked round bottom flask equipped with a stirrer, a thermometer, and a condenser, 144.0 g (1.0 mol) of 1-naphthol (reagent), 104.0 g (1.0 mol) of styrene monomer (reagent), 2.5 g of p-toluenesulfonic acid monohydrate (reagent) as an acid catalyst, and 250 g of toluene as a reaction solvent were charged at a composition ratio in which the n value was 1.0 in a theoretical structural formula of the following theoretical structure, and the temperature was raised to 100° C. with careful attention to heat generation. After that, a reaction was allowed to proceed at 100° C. for 4 hours. After that, the temperature was reduced to 60° C., 250 g of toluene, 300 g of distilled water, and 48% sodium hydroxide aqueous solution in an appropriate amount for neutralization were added, the mixture was left to stand for separation, and a by-product saline water layer as a lower layer was discarded. The upper layer was then washed and purified twice with the same amount of distilled water, and heated to carry out azeotropic dehydration. The resulting solution was subjected to microfiltration to remove impurities, and toluene was distilled under reduced pressure at a highest temperature of 120° C. to obtain 220 g of a solid material.

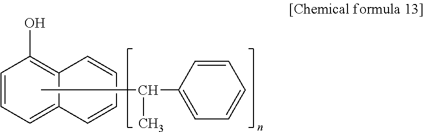

The hydroxyl equivalent of the solid material was measured according to the following measurement method to obtain a value of 244 g/eq. (theoretical value: 248 g/eq.). In the mass spectra obtained according to the following measurement method (negative ion mode), spectral peaks at an m/z of 144 corresponding to a structure of n=0, an m/z of 248 corresponding to a structure of n=1, and an m/z of 352 corresponding to a structure of n=2 were detected. Based on these analysis data, it has been confirmed that the obtained solid material had the intended molecular structure, that is, the structure of the aromatic monohydroxy compound (1) according to the above-described theoretical structure.

### (Method for Measuring Hydroxyl Equivalent)

In accordance with JIS-K0070, the hydroxyl group in a phenolic resin was acetylated with acetic anhydride-pyridine, followed by hydrolysis, and the remaining acetic acid was subjected to back titration to determine a hydroxyl equivalent.

### (Mass Spectrum Measurement Conditions)

A sample was diluted with THF into 1 mg/mL, and LC/MS was measured under the following conditions.
HPLC: ACQUITY UPLC (manufactured by Nihon Waters K.K.)
MS: SQ Detector 2 (manufactured by Nihon Waters K.K.)
Column: ACQUITY UPLC BEH C8 1.7 μm, 2.1 mm×50 mm (manufactured by Nihon Waters K.K.)
Mobile phase A: 2 mmol/L ammonium acetate aqueous solution
Mobile phase B: 2-propanol/THF (80:20)
Mobile phase mixing time and mixing ratio (A %): 0 minute (50%)→5 minutes (5%)→12 minutes (5%)→12.1 minutes (50%)→14 minutes (50%)
Flow rate: 0.25 mL/min
Analysis time: 14 minutes
Column temperature: 40° C.
Ion mode: ESI (electrospray ionization) positive or negative
Ion polarity: positive detection mode or negative detection mode
Desolvation gas flow: 700 L/hr, 250° C.
Cone gas: 70 L/hr
Ion source heater: 150° C.

### (2) Esterification Reaction: Synthesis of Trifunctional Polyester Resin (1)

In a 1-liter four-necked round bottom flask equipped with a stirrer, a thermometer, a dropping funnel, and a nitrogen gas inlet, 104.2 g of the aromatic monohydroxy compound (1) (hydroxyl group: 0.42 mol) obtained in (1) described above, 37.1 g (0.14 mol) of trimesic acid chloride, 0.1 g of tetra-n-butylammonium bromide, and 300 g of toluene were charged at a composition ratio in which the n value was 1.0 in the theoretical structural formula of the following theoretical structure and the active ester group equivalent weight was 300 g/eq. The mixture was stirred while nitrogen gas was blown, leading to complete dissolution. Then, 67.2 g (0.42 mol) of a 25% caustic soda aqueous solution was added dropwise at 30° C. over 1 hour while the temperature was finally raised to 60° C. with careful attention to heat generation. After that, the solution was further continuously stirred at 60° C. for 2 hours, 80 g of distilled water was added, the solution was left to stand for separation, and a by-product saline water layer as a lower layer was discarded. The upper layer was then washed and purified twice with the same amount of distilled water, and heated to carry out azeotropic dehydration. This solution was subjected to microfiltration to remove impurities, and toluene was distilled under reduced pressure at a highest temperature of 180° C. to obtain 108 g of a solid material.

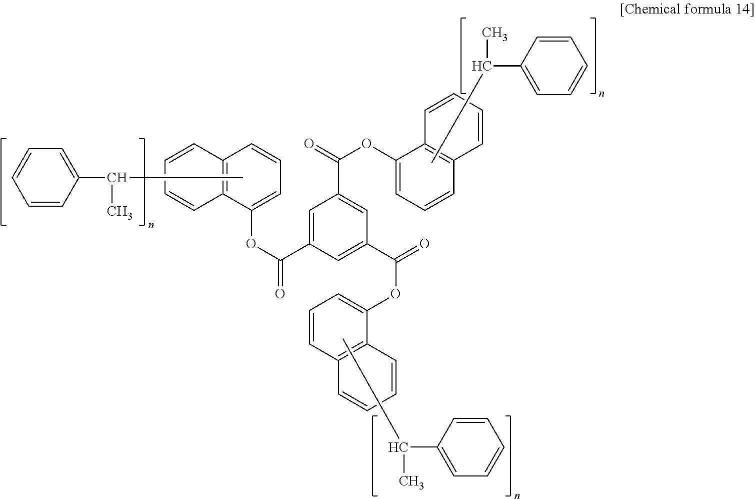

In the measurement of the mass spectrum (positive ion mode) of the obtained solid material, a spectral peak at an m/z of 900 corresponding to a structure of n=1 was detected. Based on these analysis data, it has been confirmed that the obtained solid material had the intended molecular structure, that is, the structure of the polyester resin (1) according to the above-described theoretical structure.

### <Example 2> Synthesis of Trifunctional Polyester Resin (2)

### (1) Synthesis of Aromatic Monohydroxy Compound (2)

In a 1-liter four-necked round bottom flask equipped with a stirrer, a thermometer, and a condenser, 144.0 g (1.0 mol) of 1-naphthol (reagent), 108.0 g (1.0 mol) of benzyl alcohol (reagent), and 2.5 g of p-toluenesulfonic acid monohydrate (reagent) as an acid catalyst were charged at a composition ratio in which the n value was 1.0 in the theoretical structural formula of the following theoretical structure, and the temperature was raised to 160° C. with careful attention to heat generation. After that, a reaction was allowed to proceed at 160° C. for 4 hours. After that, the temperature was reduced to 60° C., 500 g of toluene, 300 g of distilled water, and 48% sodium hydroxide aqueous solution in an appropriate amount for neutralization were added, the mixture was left to stand for separation, and a by-product saline water layer as a lower layer was discarded. The upper layer was then washed and purified twice with the same amount of distilled water, and heated to carry out azeotropic dehydration. The solution was subjected to microfiltration to remove impurities, and toluene was distilled under reduced pressure at a highest temperature of 120° C. to obtain 220 g of a solid material.

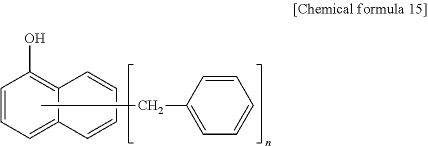

The hydroxyl equivalent of the solid material was 230 g/eq. (theoretical value: 234 g/eq.), and in the mass spectrum (negative ion mode), spectral peaks at an m/z of 144 corresponding to a structure of n=0, an m/z of 234 corresponding to a structure of n=1, and an m/z of 324 corresponding to a structure of n=2 were detected. Based on these analysis data, it has been confirmed that the obtained solid material had the intended molecular structure, that is, the structure of the aromatic monohydroxy compound (2) according to the above-described theoretical structure.

### (2) Esterification Reaction: Synthesis of Trifunctional Active Ester Resin (2)

In a 1-liter four-necked round bottom flask equipped with a stirrer, a thermometer, a dropping funnel, and a nitrogen gas inlet, 98.3 g of the aromatic monohydroxy compound (2) (hydroxyl group: 0.42 mol) obtained in (1) described above, 37.1 g (0.12 mol) of trimesic acid chloride, 0.1 g of tetra-n-butylammonium bromide, and 300 g of toluene were charged at a composition ratio in which the n value was 1.0 in the theoretical structural formula of the following theoretical structure and the active ester group equivalent weight was 286 g/eq. The mixture was stirred while nitrogen gas was blown, leading to complete dissolution. Then, 67.2 g (0.42 mol) of a 25% caustic soda aqueous solution was added dropwise at 30° C. over 1 hour while the temperature was finally raised to 60° C. with careful attention to heat generation. After that, the solution was further continuously stirred at 60° C. for 2 hours, 80 g of distilled water was added, the solution was left to stand for separation, and a by-product saline water layer as a lower layer was discarded. The upper layer was then washed and purified twice with the same amount of distilled water, and heated to carry out azeotropic dehydration. The solution was subjected to microfiltration to remove impurities, and toluene was distilled under reduced pressure at a highest temperature of 180° C. to obtain 105 g of a solid material.

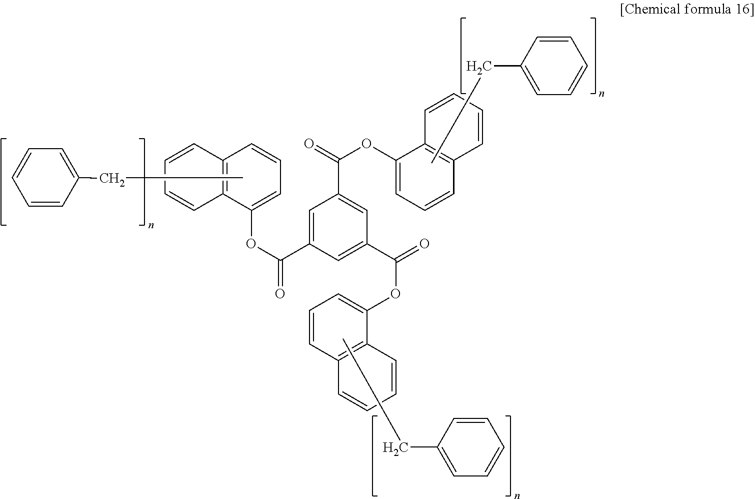

In the measurement of the mass spectrum (positive ion mode) of the obtained solid material, a spectral peak at an m/z of 860 corresponding to a structure of n=1 was detected. Based on these analysis data, it has been confirmed that the obtained solid material had the intended molecular structure, that is, the structure of the polyester resin (2) according to the above-described theoretical structure.

### <Example 3> Synthesis of Trifunctional Polyester Resin (3)

(1) Preparation of Aromatic Monohydroxy Compound (3)

As an aromatic monohydroxy compound (3), styrenated phenol SP—F containing 75% of a structure of n=1, 23% of a structure of n=2, and 0.6% of a structure of n=3 in the following structure (manufactured by SANKO CO., LTD., hydroxyl value: 258 mg KOH/g) was prepared.

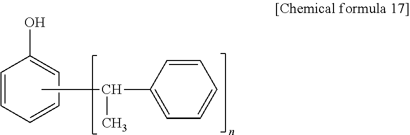

### (2) Esterification Reaction: Synthesis of Trifunctional Active Ester Resin (3)

In a 1-liter four-necked round bottom flask equipped with a stirrer, a thermometer, a dropping funnel, and a nitrogen gas inlet, 91.3 g of the aromatic monohydroxy compound (3) (hydroxyl group: 0.42 mol), 37.1 g (0.14 mol) of trimesic acid chloride, 0.1 g of tetra-n-butylammonium bromide, and 300 g of toluene were charged at a composition ratio in which the active ester group equivalent weight was 271 g/eq., in the following theoretical structure. The mixture was stirred while nitrogen gas was blown, leading to complete dissolution. Then, 67.2 g (0.42 mol) of a 25% caustic soda aqueous solution was added dropwise at 30° C. over 1 hour while the temperature was finally raised to 60° C. with careful attention to heat generation. After that, the solution was further continuously stirred at 60° C. for 2 hours, 80 g of distilled water was added, the solution was left to stand for separation, and a by-product saline water layer as a lower layer was discarded. The upper layer was then washed and purified twice with the same amount of distilled water, and heated to carry out azeotropic dehydration. The solution was subjected to microfiltration to remove impurities, and toluene was distilled under reduced pressure at a highest temperature of 180° C. to obtain 102 g of a solid material.

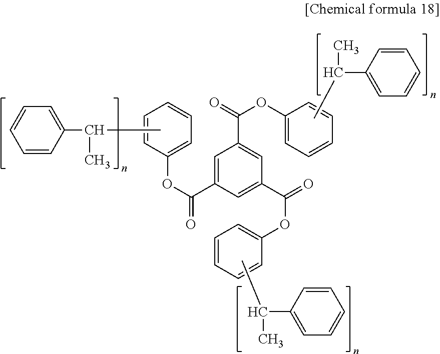

In the measurement of the mass spectrum (positive ion mode) of the obtained solid material, spectral peaks at an m/z of 751 corresponding to a structure of n=1 and an m/z of 1,063 corresponding to a structure of n=2 were detected. Based on these analysis data, it has been confirmed that the obtained solid material had the intended molecular structure, that is, the structure of the polyester resin (3) according to the above-described theoretical structure.

### <Example 4> Synthesis of Trifunctional Polyester Resin (4)

In a 1-liter four-necked round bottom flask equipped with a stirrer, a thermometer, a dropping funnel, and a nitrogen gas inlet, 34.7 g of the aromatic monohydroxy compound (1) (hydroxyl group: 0.14 mol) synthesized in Example 1, 47.6 g of 2-phenylphenol (hydroxyl group: 0.28 mol) (reagent), 37.1 g (0.14 mol) of trimesic acid chloride, 0.1 g of tetra-n-butylammonium bromide, and 300 g of toluene were charged at a composition ratio in which the active ester group equivalent weight was 248 g/eq., in the following theoretical structure. The mixture was stirred while nitrogen gas was blown, leading to complete dissolution. Then, 67.2 g (0.42 mol) of a 25% caustic soda aqueous solution was added dropwise at 30° C. over 1 hour while the temperature was finally raised to 60° C. with careful attention to heat generation. After that, the solution was further continuously stirred at 60° C. for 2 hours, 80 g of distilled water was added, the solution was left to stand for separation, and a by-product saline water layer as a lower layer was discarded. The upper layer was then washed and purified twice with the same amount of distilled water, and heated to carry out azeotropic dehydration. The solution was subjected to microfiltration to remove impurities, and toluene was distilled under reduced pressure at a highest temperature of 180° C. to obtain 88 g of a solid material.

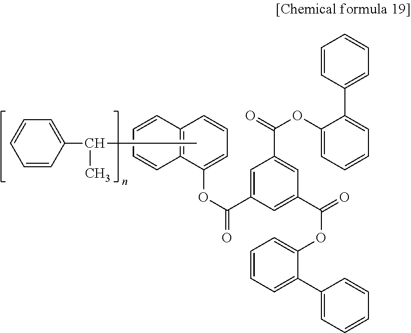

In the measurement of the mass spectrum (positive ion mode) of the obtained solid material, spectral peaks at an m/z of 745 corresponding to a structure of n=1 and an m/z of 849 corresponding to a structure of n=2 were detected. Based on these analysis data, it has been confirmed that the obtained solid material had the intended molecular structure, that is, the structure of the polyester resin (4) according to the above-described theoretical structure.

### <Example 5> Synthesis of Trifunctional Polyester Resin (5)

### (1) Synthesis of Aromatic Monohydroxy Compound (3)

In a 2-liter four-necked round bottom flask equipped with a stirrer, a thermometer, and a condenser, 144.0 g (1.0 mol) of 1-naphthol (reagent), 176.6 g (1.0 mol) of 1-chloromethyl naphthalene (reagent), 467 g of synthetic hydrotalcite KW-500SH (manufactured by Kyowa Chemical Industry Co., Ltd.), and 1,000 g of toluene as a reaction solvent were charged at a composition ratio in which the n value was 1.0 in the theoretical structural formula of the following theoretical structure, and the temperature was raised to 80° C. with careful attention to heat generation and the generation of carbon dioxide. After that, a reaction was allowed to proceed at 80° C. for 4 hours. After microfiltration, toluene was distilled under reduced pressure at a highest temperature of 120° C. to obtain 225 g of a solid material.

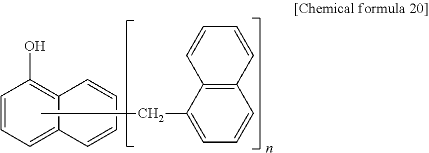

The hydroxyl equivalent of the solid material was 282 g/eq. (theoretical value: 284 g/eq.), and in the mass spectrum (negative ion mode), spectral peaks at an m/z of 144 corresponding to a structure of n=0, an m/z of 284 corresponding to a structure of n=1, and an m/z of 424 corresponding to a structure of n=2 were detected. Based on these analysis data, it has been confirmed that the obtained solid material had the intended molecular structure, that is, the structure of the aromatic monohydroxy compound (3) according to the above-described theoretical structure.

### (2) Esterification Reaction: Synthesis of Trifunctional Polyester Resin (5)

In a 1-liter four-necked round bottom flask equipped with a stirrer, a thermometer, a dropping funnel, and a nitrogen gas inlet, 119.7 g of the aromatic monohydroxy compound (3) (hydroxyl group: 0.42 mol) obtained in (1) described above, 37.1 g (0.14 mol) of trimesic acid chloride, 0.1 g of tetra-n-butylammonium bromide, and 300 g of toluene were charged at a composition ratio in which the n value was 1.0 in the theoretical structural formula of the following theoretical structure and the active ester group equivalent weight was 336 g/eq. The mixture was stirred while nitrogen gas was blown, leading to complete dissolution. Then, 67.2 g (0.42 mol) of a 25% caustic soda aqueous solution was added dropwise at 30° C. over 1 hour while the temperature was finally raised to 60° C. with careful attention to heat generation. After that, the solution was further continuously stirred at 60° C. for 2 hours, 80 g of distilled water was added, the solution was left to stand for separation, and a by-product saline water layer as a lower layer was discarded. The upper layer was then washed and purified twice with the same amount of distilled water, and heated to carry out azeotropic dehydration. The solution was subjected to microfiltration to remove impurities, and toluene was distilled under reduced pressure at a highest temperature of 180° C. to obtain 132 g of a solid material.

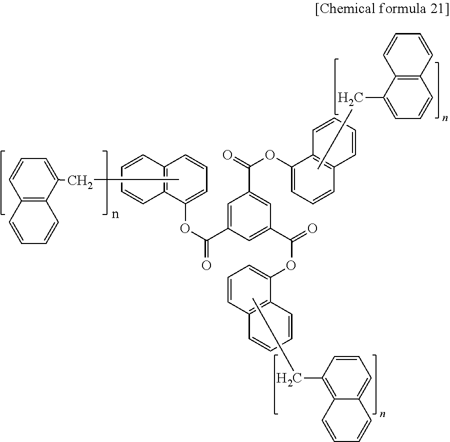

In the measurement of the mass spectrum (positive ion mode) of the obtained solid material, a spectral peak at an m/z of 1,009 corresponding to a structure of n=1 was detected. Based on these analysis data, it has been confirmed that the obtained solid material had the intended molecular structure, that is, the structure of the polyester resin (5) according to the above-described theoretical structure.

### <Comparative Example 1> Synthesis of Trifunctional Polyester Resin (6)

In a 1-liter four-necked round bottom flask equipped with a stirrer, a thermometer, a dropping funnel, and a nitrogen gas inlet, 60.5 g of 1-naphthol (hydroxyl group: 0.42 mol) (reagent), 37.1 g (0.14 mol) of trimesic acid chloride, 0.1 g of tetra-n-butylammonium bromide, and 300 g of toluene were charged at a composition ratio in which the active ester group equivalent weight was 196 g/eq. The mixture was stirred while nitrogen gas was blown, leading to complete dissolution. Then, 67.2 g (0.42 mol) of a 25% caustic soda aqueous solution was added dropwise at 30° C. over 1 hour while the temperature was finally raised to 60° C. with careful attention to heat generation. After that, the solution was further continuously stirred at 60° C. for 2 hours, 80 g of distilled water was added, and the solution was left to stand. At that time, precipitation occurred, and therefore the reaction liquid was filtered as it was, and a solid material on the filter paper was washed three times with water. The solid material on the filter paper was dried under reduced pressure in a vacuum dryer at 120° C. for 4 hours, to obtain 45 g of the solid material.

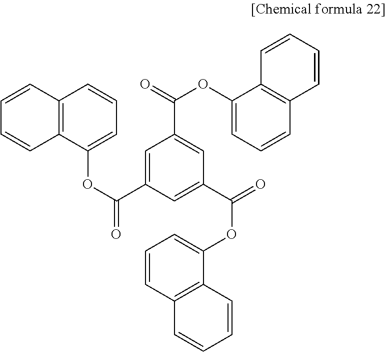 [SMILES: O=C(Oc1cccc2ccccc12)c1cc(C(=O)Oc2cccc3ccccc23)cc(C(=O)Oc2cccc3ccccc23)c1]

In the measurement of the mass spectrum (positive ion mode) of the obtained solid material, a spectral peak at an m/z of 589 was detected. Based on these analysis data, it has been confirmed that the obtained solid material had the intended molecular structure, that is, the structure of the polyester resin (6) according to the above-described theoretical structure.

### <Comparative Example 2> Synthesis of Trifunctional Polyester Resin (7)

In a 1-liter four-necked round bottom flask equipped with a stirrer, a thermometer, a dropping funnel, and a nitrogen gas inlet, 56.3 g of 2-allylphenol (hydroxyl group: 0.42 mol) (reagent), 37.1 g (0.14 mol) of trimesic acid chloride, 0.1 g of tetra-n-butylammonium bromide, and 300 g of toluene were charged at a composition ratio in which the active ester group equivalent weight was 186 g/eq. The mixture was stirred while nitrogen gas was blown, leading to complete dissolution. Then, 67.2 g (0.42 mol) of a 25% caustic soda aqueous solution was added dropwise at 30° C. over 1 hour while the temperature was finally raised to 60° C. with careful attention to heat generation. After that, the solution was further continuously stirred at 60° C. for 2 hours, 80 g of distilled water was added, the solution was left to stand for separation, and a by-product saline water layer as a lower layer was discarded. The upper layer was then washed and purified twice with the same amount of distilled water, and heated to carry out azeotropic dehydration. The solution was subjected to microfiltration to remove impurities, and toluene was distilled under reduced pressure at a highest temperature of 180° C. to obtain 76.0 g of a solid material.

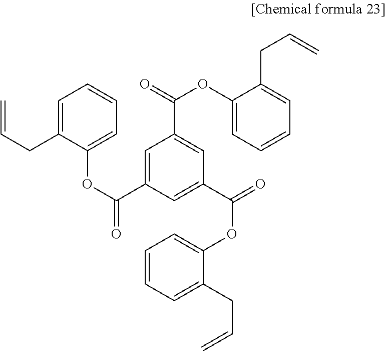 [SMILES: C=CCc1ccccc1OC(=O)c1cc(C(=O)Oc2ccccc2CC=C)cc(C(=O)Oc2ccccc2CC=C)c1]

In the measurement of the mass spectrum (positive ion mode) of the obtained solid material, a spectral peak at an m/z of 559 was detected. Based on these analysis data, it has been confirmed that the obtained solid material had the intended molecular structure, that is, the structure of the polyester resin (7) according to the above-described theoretical structure.

### <Evaluation of Solubility of Polyester Resin>

Each of the polyester resins (1) to (7) synthesized in Examples 1 to 5 and Comparative Examples 1 and 2 was added to methyl ethyl ketone (MEK) so that the solid content was 30%, and then dissolved with an ultrasonic device. After that, the presence or absence of precipitation and/or deposition after standing at room temperature for 5 hours was confirmed, and the solubility was evaluated in accordance with the following evaluation criteria.

### Evaluation Criteria:

∘ (Excellent): After standing for 5 hours, precipitation or deposition did not occur.
x (Poor): After standing for 5 hours, precipitation or deposition occurred.

TABLE 1

| | | Solvent solubility |
|---|---|---|
| Polyester resin | (1) | ∘ |
| | (2) | ∘ |
| | (3) | ∘ |
| | (4) | ∘ |
| | (5) | ∘ |
| | (6) | x |
| | (7) | ∘ |

### Examples 6 to 10 and Comparative Examples 3 and 4

### (1) Preparation of Resin Composition

Each of the synthesized polyester resins (1) to (7), a bisphenol A type liquid epoxy resin (“850S” manufactured by DIC Corporation, epoxy equivalent: 183 g/eq.), and a biphenyl aralkyl type epoxy resin (“NC3000” manufactured by Nippon Kayaku Co., Ltd., epoxy equivalent: 275 g/eq.) were melted and mixed at 150° C. in accordance with each blending composition shown in Table 2. Next, 4-dimethylaminopyridine was mixed in accordance with each blending composition shown in Table 2, to prepare each resin composition. The compositions are shown in Table 2.

### (2) Production of Cured Product

A metal mold (100 mm×100 mm×1.0 mm) coated with a release agent was filled with the prepared resin composition, and the resin composition was heated and cured at 150° C. for 10 minutes. From the metal mold, the cured product was obtained and further heated and cured at 200° C. for 3 hours, to produce a sheet-like cured product.

Note that in the resin composition of Comparative Example 3, the polyester resin (6) was not melted and was deposited, making it impossible to produce a cured product.

The cured products produced in Examples 6 to 10 and Comparative Example 4 were subjected to an evaluation test in the following manner. The results are shown in Table 3.

### [Dielectric Properties]

Each of the cured products was cut into a test piece with a predetermined size, and the dielectric constant and the dielectric loss tangent were measured by a cavity resonance method at a measurement frequency of 5.8 GHz and 23° C. using a cavity resonator perturbation method-based dielectric constant measuring device (“CP521” manufactured by Kanto Electronics Application & Development Inc.) and a network analyzer (“E8362B” manufactured by Agilent Technologies Japan, Ltd.). Five test pieces for each of the cured products were subjected to measurement (n=5), and their average value was calculated.

### [Heat Resistance]

Each of the cured products was cut into a test piece with a predetermined size, and the glass transition temperature (Tg) was measured under measurement conditions of a load of 200 mN and a temperature increasing rate of 2° C./min using a dynamic viscoelastometer (“EXSTAR6000” manufactured by SII NanoTechnology Inc.).

TABLE 2
(Table 2)

| | | | Example | | | | | Comparative Example | |
|---|---|---|---|---|---|---|---|---|---|
| | | | 6 | 7 | 8 | 9 | 10 | 3 | 4 |
| Blending | Polyester | (1) | 30 | | | | | | |
| component | resin | (2) | | 29 | | | | | |
| (part by | | (3) | | | 27 | | | | |
| mass*⁾ | | (4) | | | | 25 | | | |
| | | (5) | | | | | 34 | | |
| | | (6) | | | | | | 20 | |
| | | (7) | | | | | | | 19 |

| | | | | | | | |
|---|---|---|---|---|---|---|---|
| 850S | 11 | 11 | 11 | 11 | 11 | 11 | 11 |
| NC3000 | 11 | 11 | 11 | 11 | 11 | 11 | 11 |
| DMAP | 0.3 | 0.3 | 0.2 | 0.2 | 0.3 | 0.2 | 0.2 |

850S: Bisphenol A type liquid epoxy resin (manufactured by DIC Corporation: epoxy group equivalent: 183 g/eq.)
NC3000: Biphenyl aralkyl type epoxy resin (manufactured by Nippon Kayaku Co., Ltd.: epoxy group equivalent: 275 g/eq.)
DMAP: 4-dimethylaminopyridine (manufactured by Koei Chemical Industry Co., Ltd.)

TABLE 3

| | | Dielectric properties | | |
|---|---|---|---|---|
| | | Dielectric | Dielectric loss | Heat resistance |
| | | constant | tangent | Tg(° C.) |
| Example | 6 | 2.8 | 0.0048 | 130 |
| | 7 | 2.8 | 0.0047 | 128 |
| | 8 | 2.8 | 0.0049 | 125 |
| | 9 | 2.8 | 0.0049 | 128 |
| | 10 | 2.8 | 0.0047 | 134 |
| Comparative | 3 | — | — | — |
| Example | 4 | 2.9 | 0.0060 | 90 |

### Examples 11 to 15 and Comparative Examples 5 and 6

(1) Preparation of Resin Composition Varnish Components were mixed in solution form in accordance with each blending composition shown in Table 4, to prepare each resin composition varnish.

### (2) Production of Resin Sheet

The prepared resin composition varnish was applied onto a polyethylene terephthalate (with a thickness of 38 μm, hereinafter referred to as “PET film”) with a die coater so that the thickness of a dried resin composition layer was 40 μm, and then dried at 80 to 120° C. (100° C. on average) for 6 minutes, to produce a resin sheet.

Note that in the resin composition of Comparative Example 5, the polyester resin (6) was deposited without being dissolved, making it impossible to produce a cured sheet.

### (3) Production of Cured Product

The produced resin sheet was heated at 190° C. for 120 minutes, and the resin composition layer was thermally cured. Next, the PET film was peeled off to obtain a sheet-like cured product.

The cured products produced in Examples 11 to 15 and Comparative Example 6 were subjected to an evaluation test for dielectric properties and heat resistance in the same manner as those in Example 6 and the like. An evaluation test for smear removal was performed in the following manner. The results are shown in Table 5.

### [Smear Removal]

### (Surface Treatment of Inner Layer Substrate)

A copper-clad glass fiber cloth-epoxy resin laminated plate having a copper foil on the surface (thickness of copper foil: 18 μm, thickness of substrate: 0.8 mm, “R1515A” manufactured by Panasonic Corporation) was prepared as an inner layer substrate. The copper foil on the surface of the inner layer substrate was etched with a micro-etching agent (“CZ8101” manufactured by Mec Co., Ltd.) so that the copper etching amount was 1 μm as a roughening treatment. After that, the inner layer substrate was dried at 190° C. for 30 minutes.

### (Lamination and Curing of Resin Sheet)

Each of the resin sheets obtained in Examples and Comparative Examples was laminated on both surfaces of the inner layer substrate using a batch-type vacuum pressure laminator (2-stage build-up laminator “CVP700” manufactured by Nikko-Materials Co., Ltd.) so that the resin composition layer was bonded to the inner layer substrate. The lamination was performed by reducing the pressure for 30 seconds to an air pressure of 13 hPa or less and then pressure-bonding at a temperature of 100° C. and a pressure of 0.74 MPa for 30 seconds.

Subsequently, the laminated resin sheet was heat-pressed under an atmospheric pressure at 100° C. and a pressure of 0.5 MPa for 60 seconds to be smoothed. This resin sheet was then placed in an oven at 130° C., heated for 30 minutes, then placed in another oven at 170° C., and then heated for 30 minutes. Through the heating above, the resin composition layer was cured to obtain an insulation layer formed of a cured product of the resin composition layer. Thus, by the above-mentioned operation, an intermediate substrate having a layer structure of PET film/insulation layer/inner layer substrate/insulation layer/PET film was obtained.

### (Formation of Via Hole)

The insulation layer was processed using a CO₂ laser machining device (LK-2K212/2C) manufactured by Via Mechanics, Ltd., to form a via hole in the insulation layer. The processing was performed under conditions of a frequency of 2,000 Hz, a pulse width of 3 microseconds, an output power of 0.95 W, and a shot number of 3. The formed via hole had a top diameter (diameter) of 50 μm in the surface of the insulation layer and a diameter of 40 μm in the bottom surface of the insulation layer. The top diameter indicates the diameter of the opening of the via hole. After that, the PET films were peeled.

### (Roughening Treatment)

The intermediate substrate was immersed in Swelling Dip Securiganth P manufactured by Atotech Japan K.K., as a swelling liquid at 60° C. for 10 minutes. Subsequently, the intermediate substrate was immersed in Concentrate Compact P (an aqueous solution of 60 g/L of KMnO₄ and 40 g/L of NaOH) manufactured by Atotech Japan K.K., as a roughening liquid at 80° C. for 20 minutes. After that, the intermediate substrate was immersed in Reduction Solution Securiganth P manufactured by Atotech Japan K.K., as a neutralization liquid at 40° C. for 5 minutes. The obtained intermediate substrate is referred to as evaluation substrate A.

### (Evaluation of Smear Removal)

The surrounding area of the bottom (via bottom) of the via hole of the evaluation substrate A was observed with a scanning electron microscope (SEM). From the image obtained in this observation, the maximum smear length from the wall surface of the bottom of the via hole was measured, and evaluated in accordance with the following criteria. The maximum smear length means the length of the longest smear among the smears formed on the bottom of the via hole.
∘ (Excellent): the maximum smear length is less than 5 μm.
x (Poor): the maximum smear length is 5 μm or more.

TABLE 4

| | | | Example | | | | | Comparative Example | |
|---|---|---|---|---|---|---|---|---|---|
| | | | 11 | 12 | 13 | 14 | 15 | 5 | 6 |
| Blending | Polyester | (1) | 25 | | | | | | |
| component | resin | (2) | | 25 | | | | | |
| (part by | | (3) | | | 25 | | | | |
| mass*) | | (4) | | | | 25 | | | |
| | | (5) | | | | | 25 | | |
| | | (6) | | | | | | 25 | |
| | | (7) | | | | | | | 25 |

| | | | | | | | |
|---|---|---|---|---|---|---|---|
| 850S | 11 | 11 | 11 | 11 | 11 | 11 | 11 |
| NC3000H | 11 | 11 | 11 | 11 | 11 | 11 | 11 |
| DMAP | 0.15 | 0.15 | 0.15 | 0.15 | 0.15 | 0.15 | 0.15 |
| YL6954BH30 | 15 | 15 | 15 | 15 | 15 | 15 | 15 |
| SO-C2 | 300 | 300 | 300 | 300 | 300 | 300 | 300 |
| MEK | 15 | 15 | 15 | 15 | 15 | 15 | 15 |
| Cyclohexanone | 30 | 30 | 30 | 30 | 30 | 30 | 30 |

*Converted mass of nonvolatile components
850S: Bisphenol A type liquid epoxy resin (manufactured by DIC Corporation: epoxy group equivalent: 183 g/eq.)
NC3000H: Biphenyl aralkyl type epoxy resin (manufactured by Nippon Kayaku Co., Ltd.: epoxy group equivalent: 275 g/eq.)
DMAP: 4-dimethylaminopyridine (manufactured by Koei Chemical Industry Co., Ltd.)
YL6954BH30: Phenoxy resin (manufactured by Mitsubishi Chemical Corporation)
SO-C2: Spherical silica (manufactured by Admatechs Company Limited.)

TABLE 5

| | | Dielectric properties | | Heat | |
|---|---|---|---|---|---|
| | | Dielectric | Dielectric loss | resistance | Smear |
| | | constant | tangent | Tg(° C.) | removal |
| Example | 11 | 3.2 | 0.0022 | 161 | ∘ |
| | 12 | 3.2 | 0.0022 | 156 | ∘ |
| | 13 | 3.1 | 0.0023 | 154 | ∘ |
| | 14 | 3.2 | 0.0022 | 158 | ∘ |
| | 15 | 3.1 | 0.0022 | 160 | ∘ |
| Comparative | 5 | — | — | — | — |
| Example | 6 | 3.3 | 0.0030 | 125 | x |

As shown in Tables 1, 3, and 5, it was confirmed that when the specific polyester resin (X) of the present invention was used as the component of the resin composition, dielectric properties are dramatically improved as compared with a case where a conventional active ester resin is used. In addition, it was confirmed that the specific polyester resin (X) of the present invention exhibits high solubility in solvents and resins, and the resin composition including the polyester resin (X) achieves a cured product having excellent heat resistance and smear removal in the formation of via holes. That is, the resin composition using the specific polyester resin of the present invention and the cured product thereof are a material that can achieve low transmission loss required in a high-frequency environment, regarding a 5G device or the like at a high level without sacrificing reliability.

Where a numerical limit or range is stated herein, the endpoints are included. Also, all values and subranges within a numerical limit or range are specifically included as if explicitly written out.

As used herein the words “a” and “an” and the like carry the meaning of “one or more.”

Obviously, numerous modifications and variations of the present invention are possible in light of the above teachings. It is therefore to be understood that, within the scope of the appended claims, the invention may be practiced otherwise than as specifically described herein.

All patents and other references mentioned above are incorporated in full herein by this reference, the same as if set forth at length.

1. A polyester resin (X) represented by the following general formula (1): 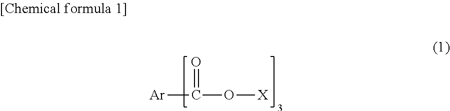
(in the formula,
Ar represents an aromatic ring optionally having a substituent, and
X each independently represents a monovalent organic group having an aromatic ring,
provided that one or more X out of three X contain at least two aromatic rings, and a total number of carbon atoms constituting the aromatic rings is 16 or more).

2. The polyester resin (X) according to claim 1, wherein the X is each independently a monovalent organic group represented by the following general formula (2): 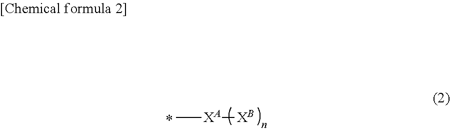
(in the formula,
X^{A} represents a (1+n)-valent organic group containing at least one aromatic ring,
X^{B} each independently represents a monovalent organic group having at least one aromatic ring,
n represents an integer of 0 to 6, and
* represents a bond to a carbonyloxy group,
provided that, in one or more X out of three X, n represents an integer of 1 to 6, and a total number of carbon atoms constituting the aromatic rings contained in X is 16 or more).

3. The polyester resin (X) according to claim 1, wherein one or more X out of three X contain a condensed polycyclic aromatic ring.

4. The polyester resin (X) according to claim 1, wherein one or more X out of three X contain three or more aromatic rings.

5. The polyester resin (X) according to claim 2, wherein the X^{A} is each independently a (1+n)-valent organic group represented by the following general formula (A): 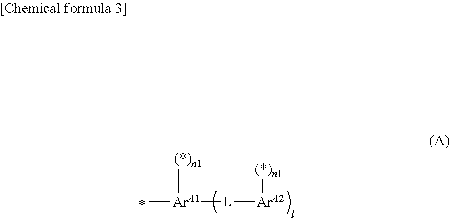
(in the formula,
Ar^{A1} and Ar^{A2} each independently represent an aromatic ring optionally having a substituent,
L represents a single bond or a divalent linking group,
l is 0 or 1,
n1 and n2 are integers that satisfy n1+n2=n,
* represents a bond to a carbonyloxy group, and
a solid star mark represents a bond to X^{B}).

6. The polyester resin (X) according to claim 2, wherein the X^{B} is each independently a monovalent organic group represented by the following general formula (B): 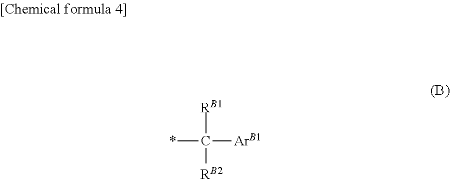
(in the formula,
R^{B1} and R^{B2} each independently represent a hydrogen atom or an alkyl group,
Ar^{B1} represents an aromatic ring optionally having a substituent, and
a solid star mark represents a bond to X^{A}).

7. The polyester resin (X) according to claim 1, wherein the polyester resin is represented by the following general formula (1-1): 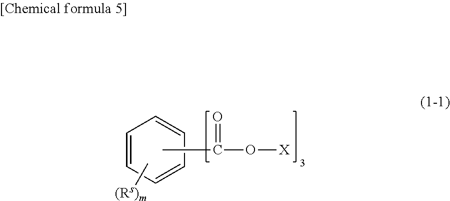
(in the formula,
X represents the same definition as described above,
R^{s} each independently represents a substituent, and
m represents an integer of 0 to 3).

8. The polyester resin (X) according to claim 1, wherein the polyester resin is a condensation reaction product of:
(x1) an aromatic tricarboxylic acid compound or an aromatic tricarboxylic acid halide compound; and
(x2) an aromatic monohydroxy compound containing at least an aromatic monohydroxy compound that contains at least two aromatic rings and in which a total number of carbon atoms constituting these aromatic rings is 16 or more.

9. A resin cross-linking agent comprising the polyester resin (X) according to claim 1.

10. A resin composition comprising the polyester resin (X) according to claim 1, and a cross-linkable resin (Y).

11. The resin composition according to claim 10, wherein the cross-linkable resin (Y) is one or more types selected from the group consisting of a thermosetting resin and a radically polymerizable resin.

12. The resin composition according to claim 10, further comprising an inorganic filler.

13. The resin composition according to claim 10, further comprising an organic solvent.

14. The resin composition according to claim 10, for an insulation layer of a printed wiring board.

15. The resin composition according to claim 10, for semiconductor sealing.

16. A resin sheet comprising: a support; and a layer of the resin composition according to claim 10, disposed on the support.

17. The resin sheet according to claim 16, wherein the support is a thermoplastic resin film or a metal foil.

18. A prepreg formed by impregnating a sheet-like fiber substrate with the resin composition according to claim 10.

19. A cured product of the resin composition according to claim 10.

20. A printed wiring board comprising an insulation layer formed of a cured product of the resin composition according to claim 10.

21. A semiconductor chip package comprising a sealing layer formed of a cured product of the resin composition according to claim 10.

22. The semiconductor chip package according to claim 21, wherein the semiconductor chip package is a Fan-Out type package.

23. A semiconductor device comprising a layer made of the cured product according to claim 19.
